(19) United States
(12) Patent Application Publication
(10) Pub. No.: US 2024/0423032 A1
(43) Pub. Date: Dec. 19, 2024

(54) DISPLAY DEVICE

(71) Applicant: Samsung Display Co., LTD., Yongin-si (KR)

(72) Inventors: DONG-YOON SO, Yongin-si (KR); JU-YEON SEO, Yongin-si (KR); HEECHUL JEON, Yongin-si (KR); MINWOO KANG, Yongin-si (KR)

(21) Appl. No.: 18/621,588

(22) Filed: Mar. 29, 2024

(30) Foreign Application Priority Data
Jun. 19, 2023 (KR) 10-2023-0078442

(51) Int. Cl. H10K 59/126; H04M 1/02; H10K 59/38; H10K 59/80; H10K 59/88

(52) U.S. Cl. CPC H10K 59/126; H10K 59/38; H10K 59/8791; H10K 59/88; H04M 1/0216

(57) ABSTRACT

A display device includes: an electronic module; and a display module in which a module region corresponding to the electronic module and a display region adjacent to the module region are defined, and which includes a display panel having a plurality of pixels disposed in the display region and an anti-reflection layer disposed on the display panel. The anti-reflection layer includes: a first light-blocking pattern which is disposed in the display region and includes a light-blocking material, and in which a plurality of openings are defined corresponding to the plurality of pixels, respectively; a color filter layer having a plurality of color filters overlapping the openings, respectively, in a plan view; and a second light-blocking pattern disposed in the module region and having the light-blocking material.

This application claims priority to Korean Patent Application No. 10-20230078442, filed on Jun. 19, 2023, and all the benefits accruing therefrom under 35 U.S.C. § 119, the content of which in its entirety is herein incorporated by reference.

### BACKGROUND

The present disclosure herein relates to a display device with improved reliability.

A multimedia apparatus, such as a television, a mobile phone, a tablet computer, a navigation system, and a game console, includes a display device for providing an image to a user.

Due to recent technological development of a display device, various types of display devices are being developed. In addition, for user convenience and product aesthetics, a display device having a display region (or active region) with a larger area and a non-display region (or bezel region) with a narrower area is being developed.

Meanwhile, the display device may include an electronic module that receives external signals, or provides output signals to the outside. The electronic module is accommodated in an outer case, etc. with a display panel, thereby constituting the display device.

### SUMMARY

The present disclosure provides a display device with improved visibility for external light reflection.

An embodiment of the invention provides a display device including an electronic module; and a display module in which a module region corresponding to the electronic module and a display region adjacent to the module region are defined, and which includes a display panel having a plurality of pixels disposed in the display region, and an anti-reflection layer disposed on the display panel, where the anti-reflection layer includes: a first light-blocking pattern which is disposed in the display region and includes a light-blocking material, and in which a plurality of openings are defined corresponding to the plurality of pixels, respectively; a color filter layer having a plurality of color filters overlapping the openings, respectively, in a plan view; and a second light-blocking pattern disposed in the module region and having the light-blocking material.

In an embodiment, the module region may include a hole region overlapping the electronic module, and a peripheral region surrounding the hole region, and the second light-blocking pattern may overlap the peripheral region in the plan view.

In an embodiment, the display module may define a module hole passing through the display panel and the anti-reflection layer and corresponding to the hole region.

In an embodiment, the module hole may include a first hole defined by passing through the display panel, and a second hole defined by passing through the second light-blocking pattern, and a size of the first hole a size of the second hole in the plan view may be the same.

In an embodiment, the display module may further include a cover plate disposed under the display panel, and the module hole may further include a third hole defined by passing through the cover plate.

In an embodiment, the size of the first hole may be greater than a size of the third hole in the plan view.

In an embodiment, the display device may further include a window disposed on the display module.

In an embodiment, the window may include a window base layer, and a light-blocking layer disposed on the window base layer.

In an embodiment, the light-blocking layer may not overlap the module region in the plan view.

In an embodiment, the display module may further include a non-display region adjacent to the display region, and the light-blocking layer may overlap the non-display region.

In an embodiment, the window may further include a protection layer disposed on the window base layer, and the light-blocking layer may be disposed between the window base layer and the protection layer.

In an embodiment, the display module may further include an input-sensing layer disposed between the display panel and the anti-reflection layer, and including a plurality of insulation layers and a plurality of sensing patterns disposed on at least one of the plurality of insulation layers.

In an embodiment, the input-sensing layer may further include an alignment mark disposed under the second light-blocking pattern, and having conductivity.

In an embodiment, the alignment mark may overlap the peripheral region in the plan view.

In an embodiment, a pattern hole, overlapping the peripheral region in the plan view, may be defined in the second light-blocking pattern, and the alignment mark may overlap the pattern hole in the plan view.

In an embodiment, the alignment mark may be disposed in a layer the same as a layer in which at least one of the plurality of sensing patterns is disposed.

In an embodiment, the plurality of insulation layers may include a first insulation layer and a second insulation layer, and the alignment mark may be disposed between the first insulation layer and the second insulation layer.

In an embodiment, the first light-blocking pattern and the second light-blocking pattern may be integrally connected to each other.

In an embodiment, a folding region, which is foldable about a virtual folding axis, and a non-folding region, which is not folded, may be defined in the display module, and the module region may overlap the non-folding region.

In an embodiment of the invention, a display device includes: an electronic module; a display module in which a module region corresponding to the electronic module and a display region adjacent to the module region are defined, and which includes a display panel having a plurality of pixels disposed in the display region, an input-sensing layer disposed on the display panel, and a functional layer disposed on the input-sensing layer; and a window disposed on the display module. The module region includes: a hole region overlapping the electronic module; and a peripheral region surrounding the hole region. The functional layer includes a module region light-blocking pattern disposed on the input-sensing layer, corresponding to the peripheral region, and having a light-blocking material.

In an embodiment, the display module may define a module hole passing through the display panel and the functional layer and corresponding to the hole region.

In an embodiment, the module hole may include a first hole defined by passing through the display panel, and a second hole defined by passing through the module region light-blocking pattern, and a size of the first hole and a size of the second hole in a plan view may be the same.

In an embodiment, the display device may further include a cover plate disposed under the display panel, and the module hole may further include a third hole defined by passing through the cover plate.

In an embodiment, the size of the first hole may be greater than a size of the third hole in the plan view.

In an embodiment, the window may include a window base layer and a light-blocking layer disposed on the window base layer, and the light-blocking layer may not overlap the module region in a plan view.

In an embodiment, the functional layer may further include: a display region light-blocking pattern which is disposed in the display region and includes the light-blocking material, and in which a plurality of openings are defined corresponding to the plurality of pixels, respectively; and a color filter layer including a plurality of color filters overlapping the openings, respectively, in a plan view.

In an embodiment, a folding region, which is foldable about a virtual folding axis, and a non-folding region, which is not folded, may be defined in the display module, and the module region may overlap the non-folding region.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a combined perspective view of a display device according to an embodiment of the invention;

FIG. 2 is an exploded perspective view of the display device of FIG. 1;

FIG. 3 is a block diagram of the display device illustrated in FIG. 1;

FIG. 4A is a plan view of a display panel according to an embodiment of the invention;

FIG. 4B is a plan view of an input-sensing layer according to an embodiment of the invention;

FIG. 5 is a cross-sectional view illustrating a display region of a display device according to an embodiment of the invention;

FIG. 6 is a plan view of a display device according to an embodiment of the invention;

FIG. 7A is a cross-sectional view of a display device taken along line I-I′ of FIG. 6;

FIG. 7B is an enlarged view of BB′ region illustrated in FIG. 7A;

FIG. 8 is a cross-sectional view of a display device taken along line II-II′ of FIG. 6;

FIG. 9 is an enlarged view of AA′ region illustrated in FIG. 6;

FIG. 10A is a cross-sectional view illustrating a portion of a display device according to an embodiment of the invention;

FIG. 10B is an enlarged view of CC′ region illustrated in FIG. 10A;

FIG. 11A is a cross-sectional view illustrating a portion of a display device according to another embodiment of the invention;

FIG. 11B is a plan view illustrating a portion of the display device illustrated in FIG. 11A;

FIG. 12 is a cross-sectional view illustrating a portion of a display device according to still another embodiment of the invention; and

FIGS. 13 to 15 are perspective views of a display device according to an embodiment of the invention.

### DETAILED DESCRIPTION

Embodiments of the invention will be described below in more detail with reference to the accompanying drawings. The invention may, however, be embodied in different forms and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Hereinafter, embodiments of the invention will be described with reference to the accompanying drawings.

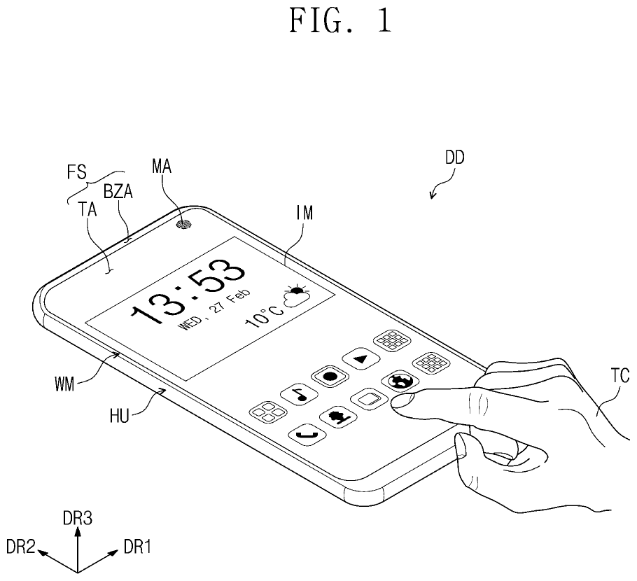

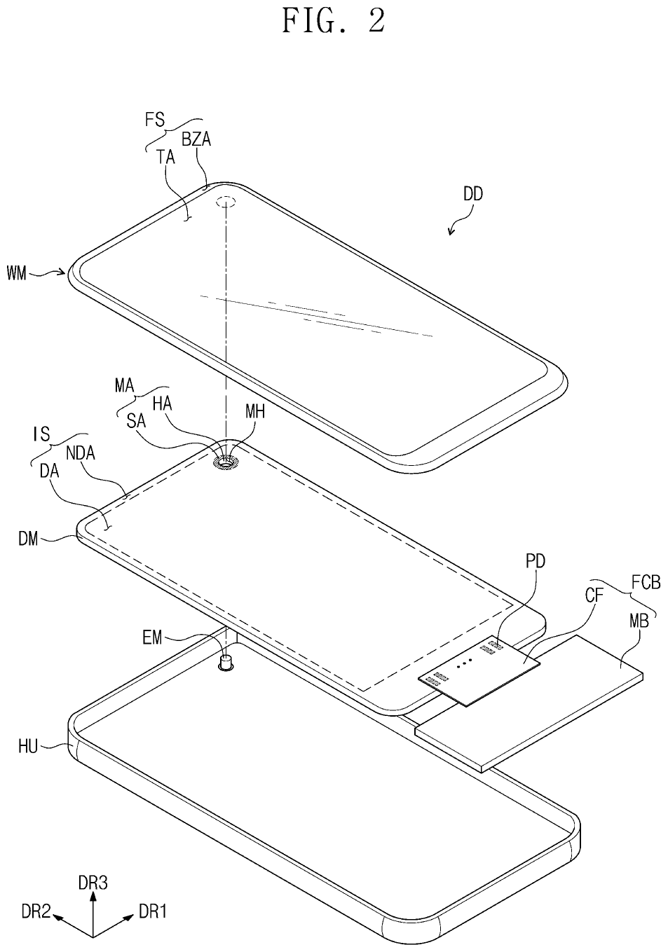

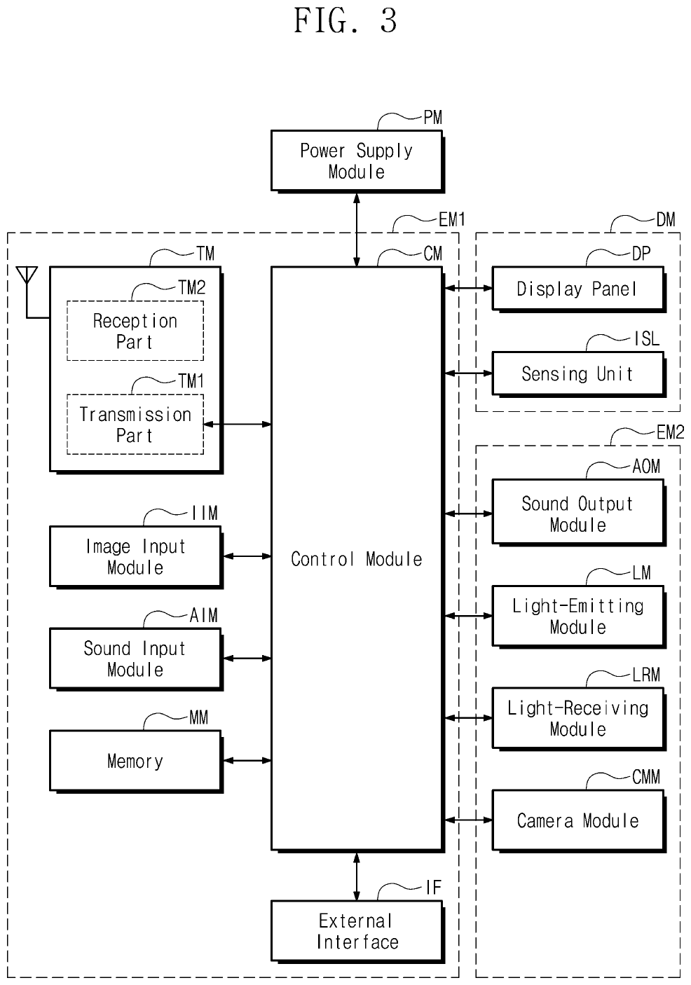

FIG. 1 is a combined perspective view of a display device according to an embodiment of the invention. FIG. 2 is an exploded perspective view of the display device of FIG. 1. FIG. 3 is a block diagram of the display device illustrated in FIG. 1. Hereinafter, an embodiment of the invention is described with reference to FIGS. 1 to 3.

A display device DD may be activated in response to electrical signals. The display device DD may include various embodiments. In an embodiment, for example, the display device DD may include a tablet computer, a laptop computer, a computer, a smart television, etc. In this embodiment, the display device DD is exemplarily illustrated as a smartphone.

As illustrated in FIG. 1, the display device DD may display an image IM on a front surface FS. The front surface may be defined to be parallel to a plane defined by a first direction DR1 and a second direction DR2. The front surface FS includes a transmission region TA and a bezel region BZA adjacent to the transmission region TA.

The display device DD displays the image IM in the transmission region TA. The image IM may include at least one of a still image or a dynamic image. FIG. 1 illustrates a clock and a plurality of icons as an example of the image IM.

The transmission region TA may have a quadrilateral shape parallel to each of the first direction DR1 and the second direction DR2. However, this is an example, the transmission region TA may have various shapes, and is not limited to any one embodiment of the invention.

The bezel region BZA is adjacent to the transmission region TA. The bezel region BZA may surround the transmission region TA. However, this is exemplarily illustrated, and the bezel region BZA may be disposed adjacent only to one side of the transmission region TA, or may also be omitted. An electronic apparatus according to an embodiment of the invention may include various embodiments, and is not limited to any one embodiment of the invention.

The normal direction of the front surface may correspond to a thickness direction DR3 (hereinafter, third direction) of the display device DD. In this embodiment, a front surface (or upper surface) and a rear surface (or lower surface) of each of members are defined on the basis of a direction in which the image IM is displayed. The front surface and the rear surface are opposed to each other in the third direction DR3.

Directions indicated by the first to third directions DR1, DR2, and DR3 may be relative concepts and may thus be changed to other directions. Hereinafter, the first to third directions refer to the directions indicated respectively by the first to third directions DR1, DR2, and DR3, and are denoted as the same reference numerals or symbols.

The display device DD according to an embodiment of the invention may detect a user's input TC applied from the outside. The user's input TC includes various types of external inputs such as a part of a user's body, light, heat, or pressure. In addition, the display device DD may detect not only an input in contact with the display device DD but also an input in close proximity to, or adjacent to the display device DD.

In this embodiment, the user's input TC is illustrated as a user's hand applied to the front surface. However, this is exemplarily illustrated, and the user's input TC may be provided in various forms as previously described. In addition, the display device DD may also detect the user's input TC applied to a side surface or a rear surface of the display device DD according to the structure of the display device DD, and is not limited to any one embodiment of the invention.

The display device DD may include a window WM, a display module DM, a printed circuit board FCB, an electronic module EM, and a housing HU. The window WM is coupled to the housing HU to define the exterior of the display device DD.

The window WM is disposed on the display module DM to cover a front surface IS of the display module DM. The window WM may include an optically transparent insulating material. In an embodiment, for example, the window WM may include glass or plastic. The window WM may have a multi-layer or single-layer structure. In an embodiment, for example, the window WM may have a stacked structure of a plurality of plastic films bonded to each other by an adhesive, or have a stacked structure of a glass substrate and a plastic film bonded to each other by an adhesive.

The window WM includes a front surface FS exposed to the outside. The front surface FS of the display device DD may be defined substantially by the front surface FS of the window.

In particular, the transmission region TA may be an optically transparent region. The transmission region TA may have a shape corresponding to a display region DA. In an embodiment, for example, the transmission region TA overlaps the entire surface, or at least a portion of the display region DA. The image IM displayed in the display region DA of the display module DM may be viewed from the outside through the transmission region TA.

The bezel region BZA may be a region having a relatively lower light transmittance than a light transmittance of the transmission region TA. The bezel region BZA defines the shape of the transmission region TA. The bezel region BZA may be adjacent to the transmission region TA, and surround the transmission region TA.

The bezel region BZA may have a predetermined color. When the window WM is provided as a glass or plastic substrate, the bezel region BZA may be a colored layer printed on, or deposited onto, one surface of the glass or plastic substrate. In addition, the bezel region BZA may also be defined by coloring the corresponding region of the glass or plastic substrate.

The bezel region BZA may cover a non-display region NDA of the display module DM, and may thus block the non-display region NDA from being visible to the outside. Meanwhile, this is exemplarily illustrated, and the bezel region BZA may also be omitted in the window WM according to an embodiment of the invention.

The display module DM may display the image IM and detect the external input TC. The display module DM includes the front surface IS having the display region DA and the non-display region NDA. The display region DA may be activated in response to electrical signals.

In this embodiment, the display region DA may be a region in which the image IM is displayed, and at the same time, a region in which the external input TC is detected. The transmission region TA overlaps at least the display region DA. In an embodiment, for example, the transmission region TA overlaps the entire surface or at least a portion of the display region DA. Accordingly, a user may view the image IM or provide the external input TC through the transmission region TA. However, this is exemplarily illustrated, and in the display region DA, a region in which the image IM is displayed and a region in which the external input TC is detected may also be separated, and the display region DA is not limited to any one embodiment of the invention.

The non-display region NDA may be a region covered by the bezel region BZA. The non-display region NDA is adjacent to the display region DA. The non-display region NDA may surround the display region DA. In the non-display region NDA, a driving circuit, driving lines, or the like for driving the display region DA may be disposed.

Various signal lines or pads PD for providing electrical signals to the display region DA, an electronic element, or the like may be disposed in the non-display region NDA. The non-display region NDA may be covered by the bezel region BZA, and may thus be invisible from the outside.

In this embodiment, the display module DM is assembled in a state where the display region DA and the non-display region NDA are flat toward the window WM. However, this is exemplarily illustrated, and a portion of the non-display region NDA of the display module DM may be bent. At this time, the portion of the non-display region NDA may face the rear surface of the display device DD, so that the bezel region BZA in the front surface of the display device DD may be reduced. Alternatively, the display module DM may be assembled in a state where a portion of the display region DA is also bent. Alternatively, the non-display region NDA may also be omitted in the display module DM according to an embodiment of the invention.

Referring to FIG. 3, the display module DM may include a display panel DP and an input-sensing layer ISL (or sensing unit). The display panel DP may be a component that substantially generates the image IM. The image IM generated from the display panel DP is viewed to a user in the outside through the transmission region TA.

The input-sensing layer ISL detects the external input TC applied from the outside. As previously described, the input-sensing layer ISL may detect the external input TC provided to the window WM.

A module region MA may be defined in the display module DM. The module region MA may have a relatively higher transmittance than the display region DA for the same area. The module region MA is defined at a position corresponding to an electronic module EM to be described later.

At least a portion of the module region MA may be surrounded by the display region DA. In this embodiment, the module region MA is spaced apart from the non-display region NDA. The module region MA is illustrated to be defined inside the display region DA such that the entire rim of the module region MA is surrounded by the display region DA. In a combined state of the display device DD according to this embodiment, the module region MA may be defined at a position displayed in the transmission region TA and spaced apart from the bezel region BZA.

In this embodiment, the module region MA may include a hole region HA and a peripheral region SA. The hole region HA may be disposed at the center of the module region MA, and the peripheral region SA may surround the rim of the hole region HA. The peripheral region SA may be a region that looks black when viewed from the outside. Detailed description of this will be made later.

The display module DM may include a module hole MH defined in the hole region HA and passing through the display module DM. The module hole MH may pass through at least one of the display panel DP or the input-sensing layer ISL. The peripheral region SA may extend substantially along the rim of the module hole MH. The rim of the hole region HA may have a shape corresponding to the module hole MH in a plan view.

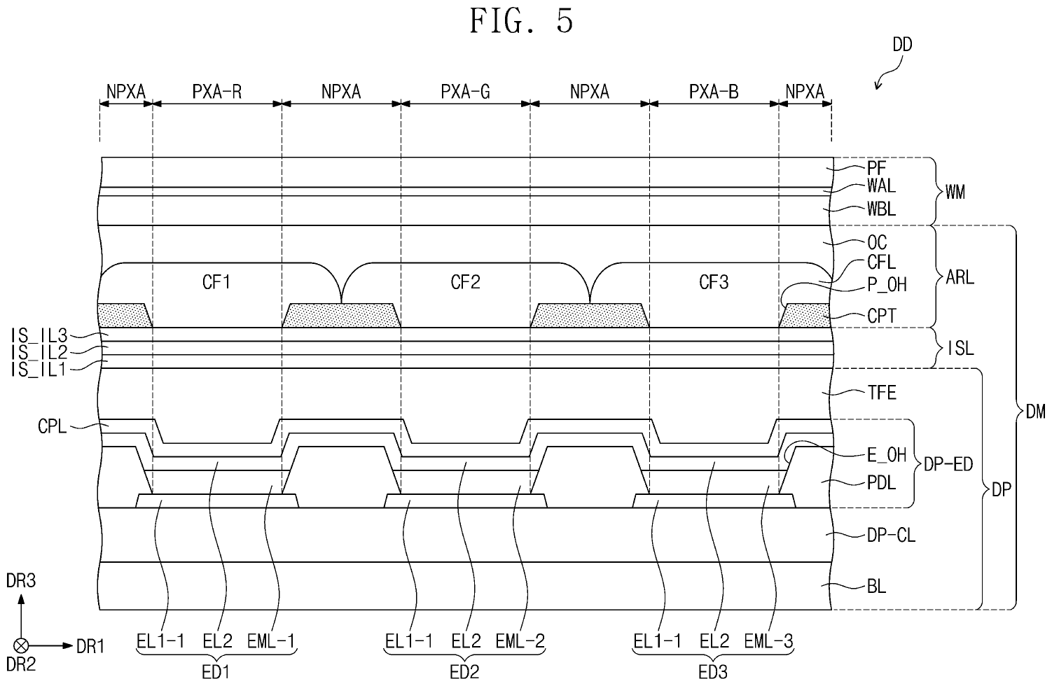

Although not illustrated in the drawing, the display module DM may further include an anti-reflection layer ARL (see FIG. 5) disposed on the input-sensing layer ISL. The anti-reflection layer ARL may be a layer that selectively transmits light emitted from the display panel DP. The anti-reflection layer ARL may include a pigment or dye, and may be a layer that reduces the reflectance for external light incident from the outside of the display device DD. Detailed description of this will be made later.

The printed circuit board FCB may be connected to the display module DM. The printed circuit board FCB may include a flexible substrate CF and a main substrate MB. The flexible substrate CF may include an insulation film and conductive lines mounted on the insulation film. The conductive lines are connected to the pads PD to electrically connect the printed circuit board FCB to the display module DM.

In this embodiment, the flexible substrate CF may be assembled in a bent state. Accordingly, the main substrate MB may be disposed on the rear surface of the display module DM, and may thus be stably accommodated in a space provided in the housing HU. Meanwhile, in this embodiment, the flexible substrate CF may also be omitted, and at this time, the main substrate MB may also be directly connected to the display module DM.

The main substrate MB may include signal lines and electronic elements that are not illustrated in the drawing. The electronic elements may be connected to the signal lines, and may thus be electrically connected to the display module DM. The electronic elements generate various electrical signals such as a signal for generating the image IM or a signal for detecting the external input TC, or processes the detected signals. Meanwhile, the main substrate MB may also be provided in plurality corresponding to each of the electrical signals for generating and processing, and is not limited to any one embodiment of the invention.

In the display device DD according to an embodiment of the invention, the driving circuit for providing electrical signals to the display region DA may also be directly mounted on the display module DM. At this time, the driving circuit may be mounted in the form of a chip, or may be formed with pixels PX. At this time, the printed circuit board FCB may have a reduced area or may be omitted. The display device DD according to an embodiment of the invention may include various embodiments, and is not limited to any one embodiment of the invention.

The electronic module EM is disposed under the window WM. The electronic module EM may overlap the module hole MH in a plan view, and overlap the hole region HA. The electronic module EM may receive an external input transmitted through the hole region HA, or provide an output through the hole region HA. As used herein, the “plan view” is a view in a thickness direction (a third direction DR3) of a base layer BL.

A reception part for receiving the external input or an output part for providing the output, among the electronic module EM, may overlap the hole region HA in a plan view. The electronic module EM may be disposed on the rear surface of the display module DM, or at least a portion of the electronic module EM may also be disposed in the module hole MH. According to an embodiment of the invention, since the electronic module EM is disposed overlapping the display region DA in a plan view, it may be possible to prevent the increase of the bezel region BZA.

Referring to FIG. 3, the display device DD may include the display module DM, a power supply module PM, a first electronic module EM1, and a second electronic module EM2. The display module DM, the power supply module PM, the first electronic module EM1, and the second electronic module EM2 may be electrically connected to each other. FIG. 3 exemplarily illustrates the display panel DP and the input-sensing layer ISL among components of the display module DM.

The first electronic module EM1 and the second electronic module EM2 include various functional modules for driving the display device DD. The first electronic module EM1 may be directly mounted on a motherboard that is electrically connected to the display panel DP, or mounted on a separate substrate to be electrically connected to the motherboard through a connector (not shown), etc.

The first electronic module EM1 may include a control module CM, a wireless communication module TM, an image input module IIM, a sound input module AIM, a memory MM, and an external interface IF. Some of the above-mentioned modules may not be mounted on the motherboard, and may also be electrically connected to the motherboard through a flexible circuit board.

The control module CM controls overall operations of the display device DD. The control module CM may be a microprocessor. In an embodiment, for example, the control module CM activates or deactivates the display panel DP. The control module CM may control other modules such as the image input module IIM or the sound input module AIM on the basis of a touch signal received from the display panel DP.

The wireless communication module TM may transmit/receive wireless signals to/from another terminal using a Bluetooth or Wi-Fi circuit. The wireless communication module TM may transmit/receive voice signals using a general communication circuit. The wireless communication module TM includes a transmission part TM1 that modifies a signal to be transmitted and transmits the signal, and includes a reception part TM2 that demodulates the received signal.

The image input module IIM processes an image signal and converts the signal into image data that is displayable on the display module DM. The sound input module AIM receives an external sound signal input through a microphone in a recording mode, a voice recognition mode, etc., and converts the signal into electrical voice data.

The external interface IF serves as an interface connected to an external charger, a wired/wireless data port, a card socket (for example, memory card, SIM/UIM card), etc.

The second electronic module EM2 may include a sound output module AOM, a light-emitting module LM, a light-receiving module LRM, a camera module CMM, and the like. The above-mentioned components may be directly mounted on the motherboard, or mounted on a separate substrate to be electrically connected to the display module DM or electrically connected to the first electronic module EM1 through a connector (not shown), etc.

The sound output module AOM converts sound data received from the wireless communication module TM or sound data stored in the memory MM to output to the outside.

The light-emitting module LM generates light and outputs the light. The light-emitting module LM may output infrared light. In an embodiment, for example, the light-emitting module LM may include a LED element. In an embodiment, for example, the light-receiving module LRM may detect infrared light. The light-receiving module LRM may be activated when detecting infrared light at a predetermined level or more. The light-receiving module LRM may include a CMOS sensor. After the infrared light generated from the light-emitting module LM is output, the infrared light is reflected by an external subject (for example, finger or face of a user), and the reflected infrared light may be incident to the light-receiving module LRM. The camera module CMM captures an external image.

Referring to FIGS. 2 and 3, the electronic module EM according to an embodiment of the invention may include at least one of the components of the first electronic module EM1 or the second electronic module EM2. In an embodiment, for example, the electronic module EM may include at least one of a camera, a speaker, a light-detecting sensor, or a heat-detecting sensor. The electronic module EM may detect an external subject received through the hole region HA, or provide a sound signal, such as a voice, to the outside through the hole region HA. In addition, the electronic module EM may include a plurality of components, and is not limited to any one embodiment of the invention.

The electronic module EM disposed overlapping the hole region HA may view an external subject, or transmit an output signal generated in the electronic module EM to the outside, easily through the hole region HA. Although not illustrated in the drawing, the display device DD according to an embodiment of the invention may further include a transparent member disposed between the electronic module EM and the display module DM. The transparent member may be an optically transparent film, so that the external input transmitted through the module hole MH may pass through the transparent member to be transmitted to the electronic module EM. The transparent member may be attached to the rear surface of the display module DM, or disposed between the display module DM and the electronic module EM without a separate adhesion layer. The display device DD according to an embodiment of the invention may have various structures, and is not limited to any one embodiment of the invention.

According to an embodiment of the invention, the electronic module EM may be assembled overlapping the transmission region TA in a plan view. Accordingly, it may be possible to prevent the increase of bezel region BZA due to accommodation of the electronic module EM, and thus the aesthetics of the display device DD may be improved.

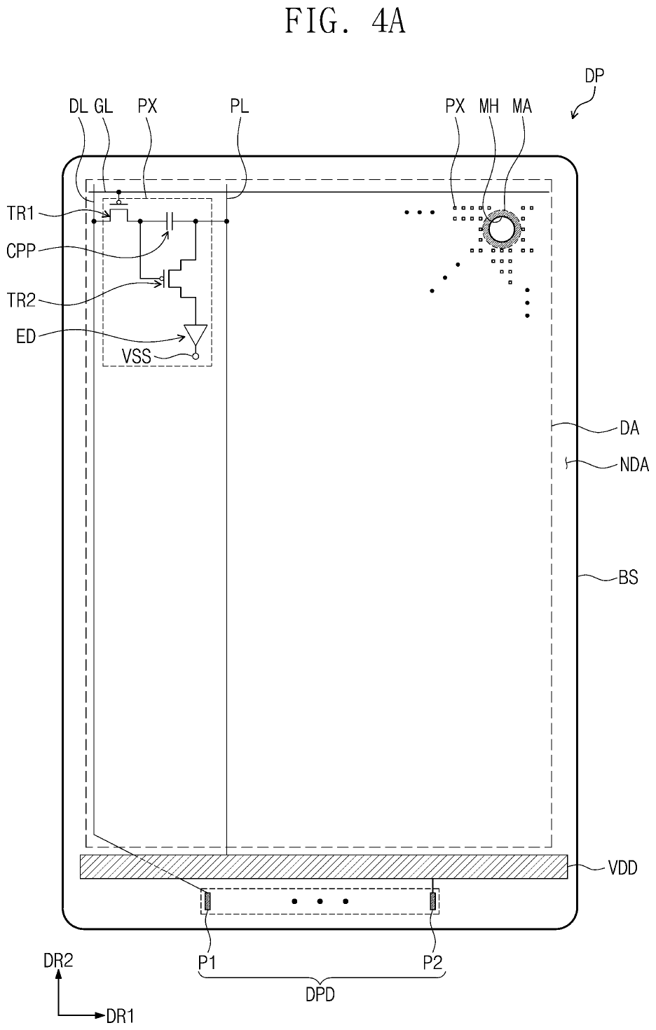

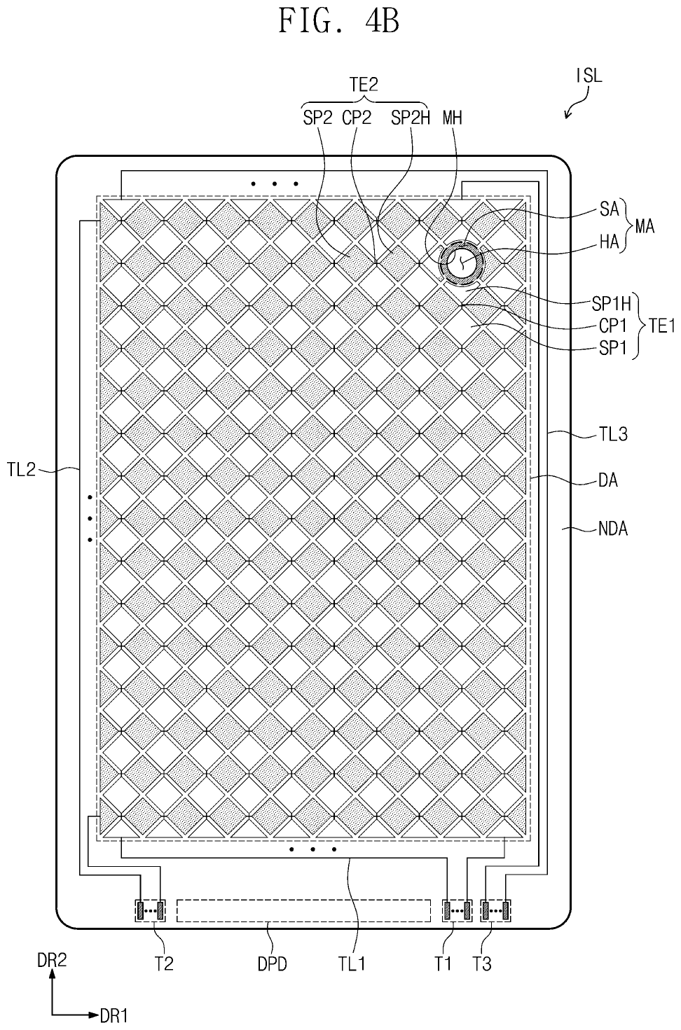

FIG. 4A is a plan view of a display panel according to an embodiment of the invention. FIG. 4B is a plan view of an input-sensing layer according to an embodiment of the invention.

Referring to FIG. 4A, the display panel DP includes a base layer BL, a plurality of pixels PX, a plurality of signal lines GL, DL, and PL, a power pattern VDD, and a plurality of display pads DPD.

A display region DA and a non-display region NDA may be regions provided by the base layer BL. The base layer BL may include an insulating substrate. In an embodiment, for example, the base layer BL may be composed of a glass substrate, a plastic substrate, or a combination thereof. In addition, the base layer BL may include a metal substrate. The base layer BL may be provided flexibly to be folded by a user, or provided rigidly not to be deformed. The base layer BL according to an embodiment of the invention may include various embodiments as long as having components such as the pixels PX or the signal lines GL, DL, and PL disposed therein, and is not limited to any one embodiment of the invention.

The signal lines GL, DL, and PL are connected to the pixels PX to transmit electrical signals to the pixels PX. A scan line GL, a data line DL, and a power line PL among the signal lines included in the display panel DP are exemplarily illustrated in the drawing. However, this is exemplarily illustrated, the signal lines GL, DL, and PL may further include at least one of a power line, an initialization voltage line, or a light-emitting control line, and are not limited to any one embodiment of the invention.

The pixels PX may be disposed in the display region DA. In this embodiment, an enlarged signal circuit diagram of one pixel PX among the plurality of pixels is exemplarily illustrated. The pixel PX may include a first thin-film transistor TR1, a capacitor CPP, a second thin-film transistor TR2, and a light-emitting element ED.

The first thin-film transistor TR1 is connected to the scan line GL and the data line DL. The capacitor CPP is connected to the first thin-film transistor TR1 and the power line PL. The second thin-film transistor TR2 is connected to the first thin-film transistor TR1, the capacitor CPP, and the light-emitting element ED. The first thin-film transistor TR1, the capacitor CPP, and the second thin-film transistor TR2 may control operations of the light-emitting element ED. The first thin-film transistor TR1 and the second thin-film transistor TR2 may be PMOS transistors. In an embodiment, for example, the first thin-film transistor TR1 and the second thin-film transistor TR2 may be LTPS transistors. The configuration of the pixel PX according to an embodiment of the invention is not limited to the embodiment illustrated in FIG. 4A. The configuration of the pixel PX illustrated in FIG. 4A is only an example, and the configuration of the pixel PX may be variously provided. In an embodiment, for example, the pixel PX may include at least three transistors, and each of the transistors may include an oxide semiconductor.

The light-emitting element ED may emit light at a time and intensity corresponding to data signal transmitted through the data line DL. In an embodiment, for example, the light-emitting element ED may include an organic light-emitting element, a quantum-dot light-emitting element, an electrophoretic element, or an electrowetting element.

The light-emitting element ED is connected to a power terminal VSS to receive a power signal (hereinafter, second power signal) different from a power signal (hereinafter, first power signal) provided through the power line PL. The light-emitting element ED may generate light corresponding to the difference between an electrical signal provided from the second thin-film transistor TR2 and the second power signal. Meanwhile, this is exemplarily illustrated, and the pixels PX may each include electronic elements having various compositions and arrangements, and are not limited to any one embodiment of the invention.

The pixels PX may be disposed around a module region MA. In this embodiment, the border between the module region MA and the display region DA may have a shape of a closed line. In this embodiment, the border between the module region MA and the display region DA is exemplarily illustrated as a circle.

The power pattern VDD is disposed in the non-display region NDA. In this embodiment, the power pattern VDD is connected to a plurality of power lines PL. Accordingly, since the display panel DP includes the power pattern VDD, a uniform first power signal may be provided for each pixel PX.

The display pads DPD may include a first pad P1 and a second pad P2. The first pad P1 may be provided in plurality, and connected to the data lines DL, respectively. The second pad P2 may be connected to the power pattern VDD to be electrically connected to the power line PL. The display panel DP may provide electrical signals, provided from the outside through the display pads DPD, to the pixels PX. In addition to the first pad P1 and the second pad P2, the display pads DPD may further include pads for receiving other electrical signals, and are not limited to any one embodiment of the invention.

Referring to FIG. 4B, an input-sensing layer ISL is illustrated in a shape corresponding to the display panel DP (see FIG. 4A). In this embodiment, the input-sensing layer ISL may be disposed on the display panel DP. However, this is exemplarily illustrated, and the input-sensing layer ISL may be disposed under the display panel DP, or embedded in the display panel DP, and is not limited to any one embodiment of the invention.

The input-sensing layer ISL may detect the external input TC (see FIG. 1), and acquire information on the position or intensity of the external input TC. The input-sensing layer ISL includes a plurality of first sensing electrodes TE1, a plurality of second sensing electrodes TE2, a plurality of lines TL1, TL2, and TL3, and a plurality of sensing pads T1, T2, and T3.

The first sensing electrodes TE1 and the second sensing electrodes TE2 are disposed in the display region DA. The input-sensing layer ISL may acquire information on the external input TC through the change in capacitance between the first sensing electrodes TE1 and the second sensing electrodes TE2.

The first sensing electrodes TE1 are arranged in a first direction DR1, and each of the first sensing electrodes TE1 extends along a second direction DR2. The first sensing electrodes TE1 may each include a first sensing pattern SP1, a first adjacency pattern SP1H, and a first connection pattern CP1 (or first auxiliary pattern).

The first sensing pattern SP1 is disposed in the display region DA. The first sensing pattern SP1 is disposed apart from a hole region HA. The first sensing pattern SP1 has a predetermined shape, and has a first area. In this embodiment, the first sensing pattern SP1 may have a diamond shape. However, this is an exemplarily illustrated, and the first sensing pattern SP1 may have various shapes, and is not limited to any one embodiment of the invention.

The first adjacency pattern SP1H is disposed adjacent to a module region MA. A module hole MH according to an embodiment of the invention passes through the input-sensing layer ISL. The first adjacency pattern SP1H has a second area smaller than the first area of the first sensing pattern SP1. The first adjacency pattern SP1H may have a shape of the same diamond as a shape of the first sensing pattern SP1 minus a region overlapping the module region MA in a plan view.

In this embodiment, the first connection pattern CP1 extends along the second direction DR2. The first connection pattern CP1 is connected to the first sensing pattern SP1. The first connection pattern CP1 may be disposed between two first main patterns SP1 to connect the two first main patterns SP1. Alternatively, the first connection pattern CP1 is disposed between the first sensing pattern SP1 and the first adjacency pattern SP1H to connect the first sensing pattern SP1 and the first adjacency pattern SP1H.

The second sensing electrodes TE2 are arranged along the second direction DR2, and each of the second sensing electrodes TE2 extends along the first direction DR1. The second sensing electrodes TE2 may each include a second sensing pattern SP2, a second adjacency pattern SP2H, and a second connection pattern CP2 (or second auxiliary pattern).

The second sensing pattern SP2 is disposed apart from the module region MA. The second sensing pattern SP2 may be spaced apart from the first sensing pattern SP1. The first sensing pattern SP1 and the second sensing pattern SP2 may not be in contact with each other, and may thus transmit/receive electrical signals independently of each other.

According to an embodiment of the invention, the second sensing pattern SP2 may have the same shape as the first sensing pattern SP1. In an embodiment, for example, the second sensing pattern SP2 may have a diamond shape. However, this is exemplarily illustrated, and the second sensing pattern SP2 may have various shapes, and is not limited to any one embodiment of the invention.

The second adjacency pattern SP2H is disposed adjacent to the module region MA. The second adjacency pattern SP2H has a smaller area than an area of the second sensing pattern SP2 in a plan view. The second adjacency pattern SP2H may have a shape of the same diamond as a shape of the second sensing pattern SP2 minus a region overlapping the module region MA in a plan view.

The second connection pattern CP2 extends along the first direction DR1. The second connection pattern CP2 is connected to the second sensing pattern SP2. The second connection pattern CP2 may be disposed between two second main patterns to connect the two second main patterns. Alternatively, the second connection pattern CP2 is disposed between the second sensing pattern SP2 and the second adjacency pattern SP2H to connect the second sensing pattern SP2 and the second adjacency pattern SP2H.

The sensing lines TL1, TL2, and TL3 are disposed in the non-display region NDA. The sensing lines TL1, TL2, and TL3 may include first sensing lines TL1, second sensing lines TL2, and third sensing lines TL3.

The first sensing lines TL1 are connected to the first sensing electrodes TE1, respectively. In this embodiment, the first sensing lines TL1 are connected to lower ends of opposite ends of the first sensing electrodes TE1, respectively.

The second sensing lines TL2 are connected to ends of the second sensing electrodes, respectively. In this embodiment, the second sensing lines TL2 are connected to left ends of opposite ends of the second sensing electrodes TE2, respectively.

The third sensing lines TL3 are connected to upper ends of the opposite ends of the first sensing electrodes TE1, respectively. According to an embodiment of the invention, the first sensing electrodes TE1 may be connected to each of the first sensing lines TL1 and the third sensing lines TL3. Accordingly, for the first sensing electrodes TE1 which are relatively longer than the second sensing electrodes TE2, sensitivity according to a region may be maintained uniformly. Meanwhile, this is exemplarily illustrated, and in the input-sensing layer ISL according to an embodiment of the invention, the third sensing lines TL3 may be omitted, and are not limited to any one embodiment of the invention.

The sensing pads T1, T2, and T3 are disposed in the non-display region NDA. The sensing pads T1, T2, and T3 may include first sensing pads T1, second sensing pads T2, and third sensing pads T3. The first sensing pads T1 are connected to the first sensing lines TL1, respectively, to provide external signals to the first sensing electrodes TE1. The second sensing pads T2 are connected to the second sensing lines TL2, respectively, and the third sensing pads T3 are connected to the third sensing lines TL3, respectively, to be electrically connected to the second sensing electrodes TE2.

FIG. 5 is a cross-sectional view illustrating a display region of a display device according to an embodiment of the invention. Hereinafter, description overlapping with what is previously described will be omitted.

Referring to FIG. 5, a display device DD may include a display module DM and a window WM. The display module DM may include a display panel DP, an input-sensing layer ISL, and an anti-reflection layer ARL (or functional layer). The display panel DP may include a base layer BL, a circuit layer DP-CL disposed on the base layer BL, a display element layer DP-ED disposed on the circuit layer DP-CL, and an encapsulation layer TFE disposed on the display element layer DP-ED.

The base layer BL may be a member that provides a base surface on which the display element layer DP-ED is disposed. The base layer BL may be a glass substrate, a metal substrate, a polymer substrate, and the like. However, an embodiment of the invention is not limited thereto, and the base layer BL may be an inorganic layer, an organic layer, or a composite material layer in another embodiment.

The base layer BL may include a single layer or multiple layers. In an embodiment, for example, the base layer BL may include a first synthetic resin layer, a multi-layer or single-layer inorganic layer, a second synthetic resin layer disposed above the multi-layer or single-layer inorganic layer. The first synthetic resin layer and the second synthetic resin layer may each include a polyimide-based resin. In addition, the first synthetic resin layer and the second synthetic resin layer may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the term “˜˜-based” resin refers to including the functional group of “˜˜”.

The circuit layer DP-CL may include an insulation layer, a semiconductor pattern, a conductive pattern, a signal line, and the like. The circuit layer DP-CL may include a plurality of transistors (not shown). The transistors (not shown) may each include a control electrode, an input electrode, and an output electrode. In an embodiment, for example, the circuit layer DP-CL may include a switching transistor and a driving transistor for driving components of the display element layer DP-ED (for example, a first electrode, a light-emitting layer, and a second electrode).

The display element layer DP-ED may include a pixel-defining film PDL in which a pixel opening E_OH is defined, and light-emitting elements ED1, ED2, and ED3. The light-emitting elements ED1, ED2, and ED3 may correspond to the light-emitting element ED described with reference to FIG. 4A. The light-emitting elements ED1, ED2, and ED3 may include first electrodes EL1-1, EL1-2, and EL1-3 exposed through the pixel opening E_OH, light-emitting layers EML-1, EML-2, and EML-3 disposed on the first electrodes EL1-1, EL1-2, and EL1-3, and a second electrode EL2 disposed on the light-emitting layers EML-1, EML-2, and EML-3, respectively.

The display panel DP may be divided into light-emitting regions PXA-R, PXA-G, and PXA-B and non-light-emitting regions NPXA. The light-emitting regions PXA-R, PXA-G, and PXA-B and the non-light-emitting regions NPXA illustrated in FIG. 5 may be included in the display region DA illustrated in FIG. 4A. The light-emitting regions PXA-R, PXA-G, and PXA-B may be spaced apart from each other in a plan view. The light-emitting regions PXA-R, PXA-G, and PXA-B may be regions where light generated in the display element layer DP-ED is emitted. The light-emitting regions PXA-R, PXA-G, and PXA-B may include a first light-emitting region PXA-R, a second light-emitting region PXA-G, and a third light-emitting region PXA-B which are distinguished from each other. The first light-emitting region PXA-R may correspond to a red light-emitting region, the second light-emitting region PXA-G may correspond to a green light-emitting region, and the third light-emitting region PXA-B may correspond to a blue light-emitting region. The light-emitting regions PXA-R, PXA-G, and PXA-B may be separated from each other by the pixel-defining film PDL. The non-light-emitting regions NPXA may be regions disposed between the adjacent light-emitting regions PXA-R, PXA-G, and PXA-B and corresponding to the pixel-defining film PDL.

The pixel-defining film PDL may have light-absorbing characteristics. The pixel-defining film PDL may include a black coloring agent. The black coloring agent may include a black pigment or black dye. The black coloring agent may include carbon black, metal such as chrome, or an oxide thereof. The pixel-defining film PDL may cover a portion of the first electrode EL1-1, EL1-2, or EL1-3. Meanwhile, in this specification, one component overlapping the other component is not limited to one component having the same area and same shape as the other component, and also refers to one component having a different area and/or different shape from the other component.

The first electrode EL1-1, EL1-2, or EL1-3 may be an anode or cathode. In addition, the first electrode EL1-1, EL1-2, or EL1-3 may be a pixel electrode. The first electrode EL1-1, EL1-2, or EL1-3 may be a transmissive electrode, transflective electrode, or a reflective electrode. If the first electrode EL1-1, EL1-2, or EL1-3 is a transmissive electrode, the first electrode EL1-1, EL1-2, or EL1-3 may include a transparent metal oxide, for example, indium tin oxide (“ITO”), indium zinc oxide (“IZO”), zinc oxide (ZnO), indium tin zinc oxide (“ITZO”), etc. If the first electrode EL1-1, EL1-2, or EL1-3 is a transflective electrode or a reflective electrode, the first electrode EL1-1, EL1-2, or EL1-3 may include Ag, Mg, Cu, Al, Pt, Pd, Au, Ni, Nd, Ir, Cr, Li, Ca, LiF/Ca, LiF/Al, Mo, Ti, W, or a compound or mixture thereof (for example, mixture of Ag and Mg). Alternatively, the first electrode EL1-1, EL1-2, or EL1-3 may have a structure of a plurality of layers including a reflective film or a transflective film formed of or including the above-mentioned materials, and a transparent conductive film formed of or including indium tin oxide (ITO), indium zinc oxide (IZO), zinc oxide (ZnO), indium tin zinc oxide (ITZO), etc. In an embodiment, for example, the first electrode EL1-1, EL1-2, or EL1-3 may have a three-layer structure of ITO/Ag/ITO, but an embodiment of the invention is not limited thereto.

The display element layer DP-ED may include a plurality of light-emitting layers EML-1, EML-2, and EML-3. The light-emitting layers EML-1, EML-2, and EML-3 may each be provided to be patterned inside the pixel opening E_OH defined in the pixel-defining film PDL. The light-emitting layers EML-1, EML-2, and EML-3 may overlap the light-emitting regions PXA-R, PXA-G, and PXA-B, respectively. The display element layer DP-ED may include a first light-emitting layer EML-1 corresponding the first light-emitting region PXA-R, a second light-emitting layer EML-2 corresponding to the second light-emitting region PXA-G, and a third light-emitting layer EML-3 corresponding to the third light-emitting region PXA-B. The light-emitting layers EML-1, EML-2, and EML-3 may emit light in different wavelength regions. In an embodiment, for example, the first light-emitting layer EML-1 may emit red light, the second light-emitting layer EML-2 may emit green light, and the third light-emitting layer EML-3 may emit blue light.

The light-emitting layers EML-1, EML-2, and EML-3 may each include an organic light-emitting material or an inorganic light-emitting material. In an embodiment, for example, the light-emitting layers EML-1, EML-2, and EML-3 may each include a fluorescent or phosphorescent material. The light-emitting layers EML-1, EML-2, and EML-3 may each include an anthracene derivative, a pyrene derivative, a fluoranthene derivative, a chrysene derivative, a dihydro benzanthracene derivative, or a triphenylene derivative. In addition, the light-emitting layers EML-1, EML-2, and EML-3 may include a metal organic complex as a light-emitting material. The light-emitting layers EML-1, EML-2, and EML-3 may also include a quantum dot as a light-emitting material.

The light-emitting layers EML-1, EML-2, and EML-3 may each be provided as a single layer or multiple layers. In an embodiment, for example, when the first light-emitting layer EML-1 is provided as multiple layers, a charge generation layer (not shown) may be disposed between the plurality of first light-emitting layers EML-1. However, this is an example, and an embodiment of the invention is not limited thereto.

The second electrode EL2 may be a common electrode. The second electrode EL2 may be a cathode or an anode, but an embodiment of the invention is not limited thereto. For another example, when the first electrode EL1-1, EL1-2, or EL1-3 is an anode, the second electrode EL2 may be a cathode, and the first electrode EL1-1, EL1-2, or EL1-3 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

Although not illustrated in the drawing, a hole transport region (not shown) may be disposed between the first electrode EL1-1, EL1-2, or EL1-3 and the light-emitting layer EML-1, EML-2, or EML-3, and the hole transport region may include at least one of a hole transport layer, a hole injection layer, or an electron blocking layer. In addition, an electron transport region (not shown) may be disposed between the light-emitting layer EML-1, EML-2, or EML-3 and the second electrode EL2, and the electron transport region may include at least one of an electron transport layer, an electron injection layer, or a hole blocking layer. The hole transport region and the electron transport region may each be provided as a common layer, or provided to be patterned in the pixel opening E_OH.

The display element layer DP-ED may further include a capping layer CPL disposed on the second electrode EL2. The capping layer CPL may include a single layer or multiple layers. The capping layer CPL may include an organic material or an inorganic material. In an embodiment, the capping layer CPL may be an organic layer or an inorganic layer. In an embodiment, for example, when the capping layer CPL includes an inorganic material, the inorganic material may include an alkali metal compound such as LiF, an alkaline earth metal compound such as MgF2, silicon oxynitride, silicon nitride, silicon oxide, etc. In an embodiment, for example, when the capping layer CPL includes the organic material, the organic material may include α-NPD, NPB, TPD, m-MTDATA, Alq3, CuPc, TPD15(N4,N4,N4′,N4′-tetra (biphenyl-4-yl) biphenyl-4,4′-diamine), TCTA(4,4′,4″-Tris (carbazol-9-yl) triphenylamine), etc., or include an epoxy resin, or acrylate such as methacrylate.

The capping layer CPL may have a refractive index of about 1.6 or more. In an embodiment, for example, the refractive index of the capping layer CPL for light in a wavelength region of about 550 nm to about 660 nm may be about 1.6 or more. The capping layer CPL may improve light efficiency by the principle of constructive interference. The capping layer CPL may be omitted in an embodiment of the invention.

The encapsulation layer TFE may seal the display element layer DP-ED. The encapsulation layer TFE may include at least one inorganic film (hereinafter, inorganic encapsulation film). In addition, the encapsulation layer TFE may include at least one organic film (hereinafter, organic encapsulation film) and at least one inorganic encapsulation film. The inorganic encapsulation film may protect the display element layer DP-ED from moisture/oxygen, and the organic encapsulation film may protect the display element layer DP-ED from foreign substances such as dust particles. The inorganic encapsulation film may include silicon nitride, silicon oxynitride, silicon oxide, titanium oxide, aluminum oxide, or the like, and the material is not limited particularly thereto. The organic encapsulation film may include an acrylate-based compound, an epoxy-based compound, etc. The organic encapsulation film may include a photopolymerizable organic material, and the material is not limited particularly thereto.

The input-sensing layer ISL may be disposed on the display panel DP. The input-sensing layer ISL may include first to third sensing insulation layers IS-IL1, IS-IL2, and IS-IL3 stacked in sequence. The first sensing insulation layer IS-IL1 may include a single layer or multiple layers. The first sensing insulation layer IS-IL1 may include an organic material or an inorganic material. The first sensing insulation layer IS-IL1 may include at least one of silicon nitride, silicon oxynitride, or silicon oxide. The second sensing insulation layer IS-IL2 or the third sensing insulation layer IS-IL3 may each include a conductive layer. The conductive layers included in the second sensing insulation layer IS-IL2 or the third sensing insulation layer IS-IL3 may include a single layer or multiple layers. The conductive layers may include at least one metal layer and at least one transparent conductive layer. In an embodiment, for example, the conductive layers may have a three-layer structure of ITO/Ag/ITO. Detailed description of the input-sensing layer ISL will be made later.

The anti-reflection layer ARL may be disposed on the input-sensing layer ISL. The anti-reflection layer ARL may include a light-blocking pattern CPT, a color filter layer CFL, and an over-coating layer OCL. The light-blocking pattern CPT may have a pattern opening P_OH defined therein.

A material constituting the light-blocking pattern CPT is not particularly limited as long as being a light-blocking material. The light-blocking pattern CPT may have black color, and include a black coloring agent. The black coloring agent may include a black pigment or black dye. The black coloring agent may include carbon black, metal such as chrome, or an oxide thereof.

The color filter layer CFL may include a plurality of color filters CF1, CF2, and CF3. The plurality of color filters CF1, CF2, and CF3 may include a first color filter CF1, a second color filter CF2, and a third color filter CF3. The first to third color filters CF1, CF2, and CF3 may be disposed corresponding to the light-emitting layers EML-1, EML-2, and EML-3, respectively. The first to third color filters CF1, CF2, and CF3 may each include a pigment or dye. In an embodiment, for example, the first color filter CF1 may be a red filter, the second color filter CF2 may be a green filter, and the third color filter CF3 may be a blue filter.

The over-coating layer OCL may cover the light-blocking pattern CPT and the first to third color filters CF1, CF2, and CF3. The over-coating layer OCL may include an organic material. The over-coating layer OCL may be a planarization layer.

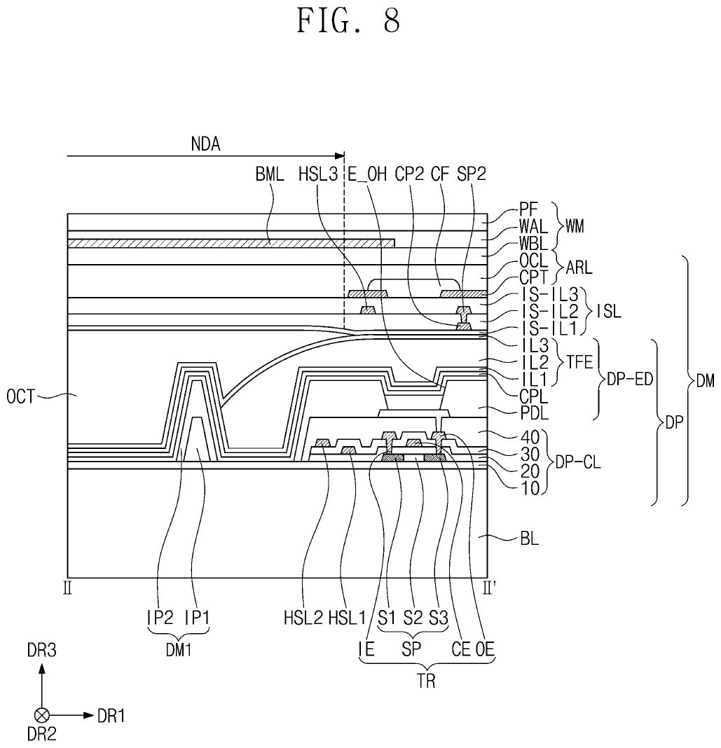

The window WM may be disposed on the anti-reflection layer ARL. The window WM may include a window base layer WBL and a protection layer PF. The window WM may further include a window adhesive layer WAL between the window base layer WBL and the protection layer PF, and although not illustrated in the drawing, a light-blocking layer BML (see FIG. 8) may be disposed on the window adhesive layer WAL. Since the window WM is disposed on the over-coating layer OCL, the display module DM may be protected from external impact. The composition of the window WM will be described in detail later.

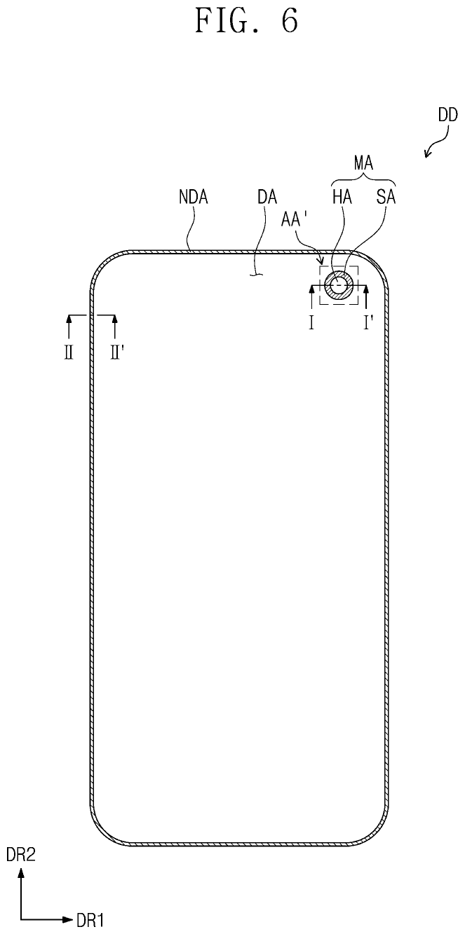

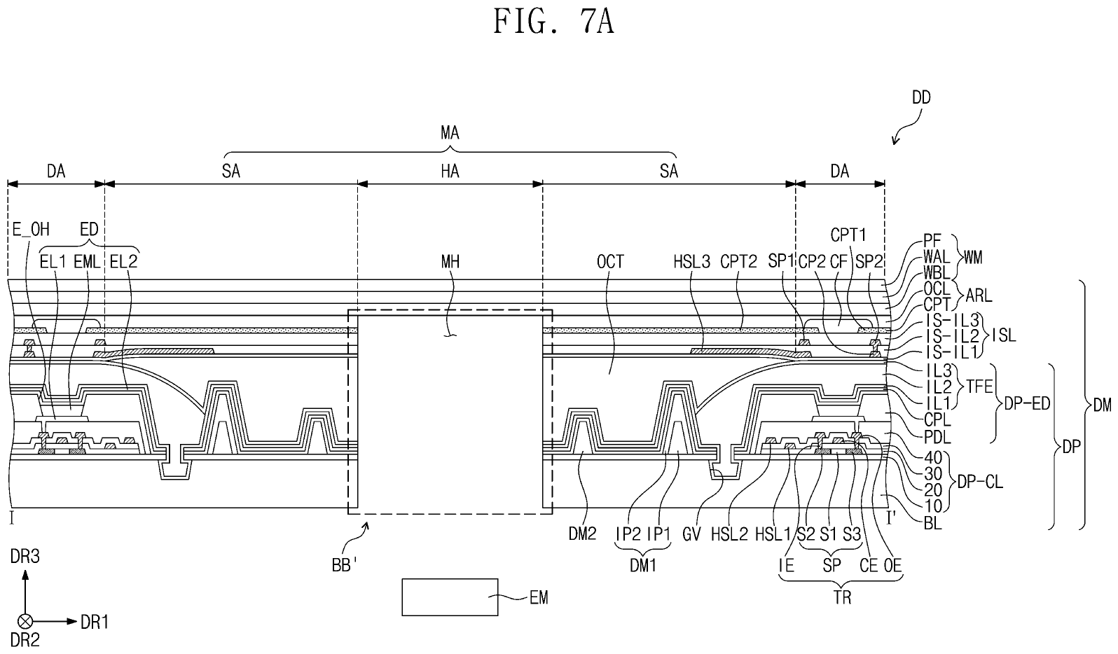

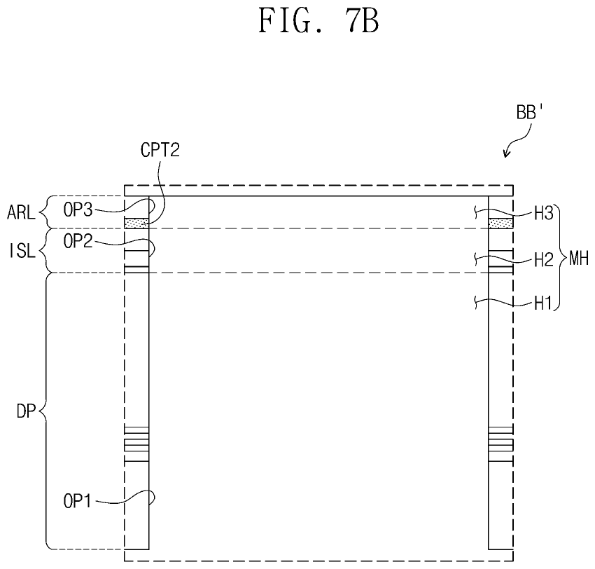

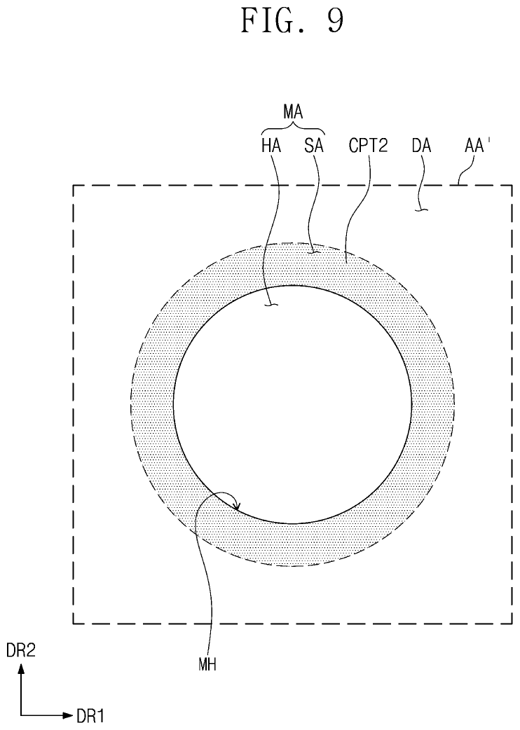

FIG. 6 is a plan view of a display device according to an embodiment of the invention. FIG. 7A is a cross-sectional view of a display device taken along line I-I′ of FIG. 6. In particular, FIG. 7A is a cross-sectional view illustrating a module region MA and a display region DA of the display device DD. FIG. 7B is an enlarged view of BB′ region illustrated in FIG. 7A. FIG. 8 is a cross-sectional view of a display device taken along line II-II′ of FIG. 6. In particular, FIG. 8 is a cross-sectional view illustrating a non-display region NDA of the display device DD. FIG. 9 is an enlarged view of AA′ region illustrated in FIG. 6. FIGS. 7A and 8 illustrate more detailed compositions of a display panel DP, an input-sensing layer ISL, and a window WM. Description overlapping with what is previously described will be omitted.

Referring to FIGS. 6 and 7A, a module region MA is surrounded by a display region DA. The display region DA may be formed corresponding to a light-emitting element ED, and the module region MA may be formed corresponding to an electronic module EM. The module region MA may include a hole region HA corresponding to a module hole MH and a peripheral region SA adjacent to the hole region HA. The module hole MH may be defined by passing through a display panel DP, an input-sensing layer ISL, and an anti-reflection layer ARL, and a peripheral region SA adjacent to the hole region HA. In the case that the electronic module EM is a camera module, the hole region HA may be a region overlapping a lens in the module region MA. The hole region HA may be a region having the highest light transmittance in the module region MA.

The display panel DP may include a base layer BL, a circuit layer DP-CL, a display element layer DP-ED, and an encapsulation layer TFE stacked in sequence.

The circuit layer DP-CL may be disposed on the base layer BL. The circuit layer DP-CL may include a plurality of insulation layers 10, 20, 30, and 40, Hall signal lines HSL1 and HSL2, and a thin-film transistor TR. The thin-film transistor TR may be either of the first thin-film transistor TR1 or the second thin-film transistor TR2 illustrated in FIG. 4A.

The insulation layers 10, 20, 30, and 40 may include first to fourth insulation layers 10, 20, 30, and 40 stacked in sequence. The first to fourth insulation layers 10, 20, 30, and 40 may each include an organic material and/or an inorganic material, and may have a single-layer or multi-layer structure.

The first insulation layer 10 is disposed on the base layer BL to cover a front surface of the base layer BL. The first insulation layer 10 may include a barrier layer and/or a buffer layer. Accordingly, the first insulation layer 10 may prevent oxygen or moisture introduced through the base layer BL from permeating a pixel. In this embodiment, the first insulation layer 10 may be optically transparent. In an embodiment, for example, the first insulation layer 10 may have a visible light transmittance of about 90% or more.

The thin-film transistor TR may be disposed on the first insulation layer 10. The thin-film transistor TR and the light-emitting element ED constitute the pixel PX (see FIG. 4A). The thin-film transistor TR may include a semiconductor pattern SP, a control electrode CE, an input electrode IE, and an output electrode OE.

The semiconductor pattern SP includes a semiconductor material. In an embodiment, for example, the semiconductor pattern SP may include a Group III element, a Group V element, a compound of a Group III element or Group V element, or an oxide semiconductor.

The semiconductor pattern SP may be divided into a channel S1, and a source S2 and a drain S3 spaced apart from each other with the channel S1 therebetween. The channel S1, the source S2, and the drain S3 may have an integral shape connecting to each other.

The channel S1 may be a region overlapping the control electrode CE in a plan view. The source S2 and the drain S3 may have a relatively higher charge mobility than the channel S1. The charge in the semiconductor pattern SP may move from the source S2 to the drain S3 through the channel S1.

The control electrode CE is disposed on the second insulation layer 20. The second insulation layer 20 is disposed on the first insulation layer 10 to cover the semiconductor pattern SP. The control electrode CE may be spaced apart from the semiconductor pattern SP with the second insulation layer 20 therebetween on a cross-section.

The input electrode IE and the output electrode OE are disposed on the third insulation layer 30. The third insulation layer 30 is disposed on the second insulation layer 20 to cover the control electrode CE.

The input electrode IE passes through the second insulation layer 20 and the third insulation layer 30 to be connected to the source S2. The output electrode OE is spaced apart from the input electrode IE and connected to the drain S3. The input electrode IE and the output electrode OE may each include a conductive material. The input electrode IE provides charge to the source S2, and the output electrode OE transfers the charge, which has been moved to the drain S3, to the light-emitting element ED.

The input electrode IE and the output electrode OE may also be omitted in the thin-film transistor TR according to this embodiment. That is, the thin-film transistor TR may also be composed only of the control electrode CE and the semiconductor pattern SP. At this time, the source S2 and the drain S3 may function as the input electrode IE and the output electrode OE, and the input electrode IE and the output electrode OE may function as connection electrodes which connect the thin-film transistor TR to other signal lines or other elements. The thin-film transistor TR according to an embodiment of the invention may have various structures, and is not limited to any one embodiment of the invention.

The display element layer DP-ED may be disposed on the circuit layer DP-CL. The display element layer DP-ED may include a light-emitting element ED and a pixel-defining film PDL.

The light-emitting element ED may include a first electrode EL1, a second electrode EL2, and a light-emitting layer EML. The light-emitting element ED may correspond to one among the first light-emitting element ED1, the second light-emitting element ED2, and the third light-emitting element ED3 illustrated in FIG. 5.

The first electrode EL is disposed on the fourth insulation layer 40. The fourth insulation layer 40 is disposed on the third insulation layer 30 to cover the thin-film transistor TR. The first electrode EL1 is connected to the output electrode OE, and electrically connected to the thin-film transistor TR.

The pixel-defining film PDL may be disposed on the fourth insulation layer 40. The pixel-defining film PDL may have a pixel opening E_OH defined therein. The pixel opening E_OH may expose at least a portion of the first electrode EL1. The light-emitting layer EML may be disposed in the pixel opening E_OH. The light-emitting layer EML may include a light-emitting material containing a fluorescent material or phosphorescent material. The light-emitting material may include an organic light-emitting material or inorganic light-emitting material, and the material is not limited to any one embodiment of the invention.

The second electrode EL2 may be disposed on the light-emitting layer EML and the pixel-defining film PDL. The area of the second electrode EL2 may cover at least the entire surface of the display region DA. Accordingly, a plurality of light-emitting elements may include one second electrode EL2 in common. However, this is exemplarily illustrated, and the second electrode EL2 may be provided for each pixel to correspond to the first electrode EL1, and is not limited to any one embodiment of the invention.

Although not illustrated in the drawing, a control layer may be disposed between the light-emitting layer EML and the first electrode EL1, or between the light-emitting layer EML and the second electrode EL2. The control layer may include an electron transport material, an electron injection material, a hole transport material, or a hole injection material. A capping layer CPL may be disposed on the second electrode EL2. The capping layer CPL may include an organic material or an inorganic material. The capping layer CPL may be disposed on the light-emitting element ED, and protect the light-emitting element ED from external moisture or foreign substances.

The encapsulation layer TFE may be disposed on the capping CPL. The encapsulation layer TFE may be disposed on the capping layer CPL to seal the display element layer DP-ED. The encapsulation layer TFE may include a first encapsulation insulation layer IL1, a second encapsulation insulation layer IL2, and a third encapsulation insulation layer IL3. However, an embodiment of the invention is not limited thereto, and the encapsulation layer TFE may further include a plurality of inorganic layers and organic layers in another embodiment.

The first encapsulation insulation layer IL1 may be an inorganic layer. The first encapsulation insulation layer IL1 may prevent external moisture or oxygen from permeating the light-emitting element ED. In an embodiment, for example, the first encapsulation insulation layer IL1 may include silicon nitride, silicon oxide, or a compound thereof. The first encapsulation insulation layer IL1 may be formed through a chemical vapor deposition process.

The second encapsulation insulation layer IL2 may be an organic layer. The second encapsulation insulation layer IL2 may be disposed on the first encapsulation insulation layer IL1, and may be in contact with the first encapsulation insulation layer IL1. The second encapsulation insulation layer IL2 may provide a flat surface onto the first encapsulation insulation layer IL1. A curve formed on an upper surface of the first encapsulation insulation layer IL1, particles existing on the first encapsulation insulation layer IL1, or the like may be covered by the second encapsulation insulation layer IL2, so that it may be possible to prevent a surface finish of the upper surface of the first encapsulation insulation layer IL1 from affecting the components to be formed on the second encapsulation insulation layer IL2. In addition, the second encapsulation insulation layer IL2 may relieve stress between the layers in contact therewith. The second encapsulation insulation layer IL2 may be formed through a spin coating, a slit coating, and a solution process such as an inkjet process.

The third encapsulation insulation layer IL3 may be disposed on the second encapsulation insulation layer IL2 to cover the second encapsulation insulation layer IL2. The third encapsulation insulation layer IL3 may be more stably disposed on a relatively flat surface than disposed on the first encapsulation insulation layer IL1. The third encapsulation insulation layer IL3 encapsulates moisture, etc. released from the second encapsulation insulation layer IL2 to prevent leaking to the outside.

The third encapsulation insulation layer IL3 may be optically transparent. In an embodiment, for example, the third encapsulation insulation layer IL3 may have a visible light transmittance of about 90% or more. The third encapsulation insulation layer IL3 may have a relatively higher light transmittance than a light transmittance of the first encapsulation insulation layer IL1. The third encapsulation insulation layer IL3 may be an inorganic layer. The third encapsulation insulation layer IL3 may include silicon oxide SiOₓ or silicon oxynitride SiON. The third encapsulation insulation layer IL3 may be formed through a chemical vapor deposition process. The first encapsulation insulation layer IL1, the second encapsulation insulation layer IL2, and the third encapsulation insulation layer IL3 may each include a plurality of layers, and are not limited to any one embodiment of the invention.

The input-sensing layer ISL may be disposed on the display panel DP. As previously described, a first sensing pattern SP1, a second sensing pattern SP2, and a second auxiliary pattern CP2 may be some components of the input-sensing layer ISL. The first sensing pattern SP1, the second sensing pattern SP2, and the second auxiliary pattern CP2 may constitute the input-sensing layer ISL together with a plurality of insulation layers IS-IL1, IS-IL2, and IS-IL3. Each of the first sensing pattern SP1, the second sensing pattern SP2, and the second auxiliary pattern CP2 may be disposed on at least one of the plurality of insulation layers IS-IL1, IS-IL2, and IS-IL3.

The input-sensing layer ISL may include first to third sensing insulation layers IS-IL1, IS-IL2, and IS-IL3 stacked in sequence. The first to third sensing insulation layers IS-IL1, IS-IL2, and IS-IL3 may each be optically transparent. In an embodiment, for example, the first to third sensing insulation layers IS-IL1, IS-IL2, and IS-IL3 may each have a visible light transmittance of about 90% or more. The first to third sensing insulation layers IS-IL1, IS-IL2, and IS-IL3 may each have an inorganic film, an organic film, or a stacked structure thereof.

In this embodiment, it is illustrated that the first sensing pattern SP1 and the second sensing pattern SP2 are disposed in the same layer, and the second auxiliary pattern CP2 is disposed on a different layer from the second sensing pattern SP2. The first sensing pattern SP1, the second sensing pattern SP2, and the second auxiliary pattern CP2 may each include a transparent conductive oxide. The second auxiliary pattern CP2 may be disposed between the first sensing insulation layer IS-IL1 and the second sensing insulation layer IS-IL2, and the second sensing pattern SP2 may pass through the second sensing insulation layer IS-IL2 to be connected to the second auxiliary pattern CP2. Meanwhile, although not illustrated in the drawing, the first auxiliary pattern CP1 (see FIG. 4B) may be disposed in the same layer as the first sensing pattern SP1 to be directly connected to the first sensing pattern SP1.

However, this is exemplarily illustrated, and the second auxiliary pattern CP2 may be disposed in the same layer as the second sensing pattern SP2, and the first auxiliary pattern CP1 may be disposed on a different layer from the first sensing pattern SP1. Alternatively, the first sensing pattern SP1 and the second sensing pattern SP2 may be disposed on different layers. The input-sensing layer ISL according to an embodiment of the invention may have various structures, and is not limited to any one embodiment of the invention.

Hall signal lines HSL1, HSL2, and HSL3 may be disposed in the module region MA. In particular, the Hall signal lines HSL1, HSL2, and HSL3 may be disposed in the peripheral region SA of the module region MA. A first Hall signal line HSL1 and a second Hall signal line HSL2 may be a plurality of signal lines GL, DL, and PL illustrated in FIG. 4A. It is illustrated that the first Hall signal line HSL1 is disposed between the second insulation layer 20 and the third insulation layer 30. The first Hall signal line HSL1 may be a scan line connected to pixels disposed adjacent to the module region MA. The first Hall signal line HSL1 may provide uniform scan signals to the pixels disposed apart from each other with the module region MA therebetween via the peripheral region SA.

It is illustrated that the second Hall signal line HSL2 is disposed between the third insulation layer 30 and the fourth insulation layer 40. The second Hall signal line HSL2 may be a data line connected to pixels disposed adjacent to the module region MA. The second Hall signal line HSL2 electrically connects the pixels disposed apart from each other with the module region MA therebetween via the peripheral region SA.

The third Hall signal line HSL3 may be disposed on the first sensing insulation layer IS-IL1 and included in the input-sensing layer ISL. It is illustrated that the third Hall signal line HSL3 is disposed between the first sensing insulation layer IS-IL1 and the second sensing insulation layer IS-IL2, but this is exemplarily illustrated, and the third Hall signal line HSL3 may also be disposed between the second sensing insulation layer IS-IL2 and the third sensing insulation layer IS-IL3. The third Hall signal line HSL3 may be a connection line connected to the sensing patterns SP1 and SP2 disposed adjacent to the module region MA.

The anti-reflection layer ARL may be disposed on the input-sensing layer ISL. The anti-reflection layer ARL may include a light-blocking pattern CPT, a color filter CF, and an over-coating layer OCL. According to an embodiment of the invention, the light-blocking pattern CPT may include a first light-blocking pattern CPT1 (or display region light-blocking pattern) disposed in the display region DA, and a second light-blocking pattern CPT2 (or module region light-blocking pattern) disposed in the module region MA. The second light-blocking pattern CPT2 may extend from the first light-blocking pattern CPT1 to be formed integrally with the first light-blocking pattern CPT1. The first light-blocking pattern CPT1 may have a pattern opening P_OH defined therein. The color filter CF may overlap the pattern opening P_OH in a plan view. The color filter CF may correspond to one of the first color filter CF1, the second color filter CF2, and the third color filter CF3 illustrated in FIG. 5. The first light-blocking pattern CPT1 may correspond to the light-blocking pattern CPT illustrated in FIG. 5.

The second light-blocking pattern CPT2 may be disposed in the peripheral region SA of the module region MA. The second light-blocking pattern CPT2 may be disposed adjacent to the hole region HA. In an embodiment, for example, the second light-blocking pattern CPT2 may extend to a boundary portion of the hole region HA and the peripheral region SA. However, an embodiment of the invention is not limited thereto, and the second light-blocking pattern CPT2 may be disposed apart from the hole region HA at a predetermined distance in a second direction DR2 in another embodiment. According to an embodiment of the invention, since the second light-blocking pattern CPT2 included in the anti-reflection layer ARL is formed along the perimeter of the hole region HA, it may be possible to prevent reflected light generated from a lower part of the electronic module EM from being visible to the outside of the display device DD in the hole region HA. Accordingly, it may be possible to provide the display device DD with reliability.

The window WM may be disposed on the anti-reflection layer ARL. The window WM may include a window base layer WBL and a protection layer PF. The window WM may further include a window adhesive layer WAL between the window base layer WBL and the protection layer PF. In addition, although not illustrated in the drawing, a light-blocking layer BML (see FIG. 8) may be disposed on the window adhesive layer WAL. According to an embodiment of the invention, the light-blocking layer BML may not be disposed in the module region MA. Accordingly, the light-blocking layer BML may not overlap the second light-blocking pattern CPT2 disposed in the module region MA in a plan view.

Referring to FIG. 7A and 7B together, the display device DD may include a module hole MH defined by passing through a portion of the display device DD. In an embodiment, for example, the module hole MH may be defined by passing through the display panel DP, the input-sensing layer ISL, and the anti-reflection layer ARL. However, an embodiment of the invention is not limited thereto, and the module hole MH may be defined by passing through only a portion of the display panel DP in another embodiment. At least a portion of the electronic module EM may be disposed in the module hole MH.

A first opening OP1 may be defined in the display panel DP, a second opening OP2 may be defined in the input-sensing layer ISL, and a third opening OP3 may be defined in the anti-reflection layer ARL. According to an embodiment of the invention, the module hole MH may include a first hole H1 where the first opening OP1 is defined, a second hole H2 where the second opening OP2 is defined, and a third hole H3 where the third opening OP3 is defined. The first to third holes H1, H2, and H3 may extend integrally to form the module hole MH together. The first opening OP1, the second opening OP2, and the third opening OP3 may be arranged along a third direction DR3. That is, the width of the module hole MH may be uniform along the third direction DR3.

The display panel DP may further include a plurality of dams DM1 and DM2, and a planarization pattern OCT, and define a groove portion GV therein. The groove portion GV, the plurality of dams DM1 and DM2, and the planarization pattern OCT may be disposed in the module region MA.

The groove portion GV may be defined in the peripheral region SA of the module region MA. The groove portion GV may be defined by at least a portion of the base layer BL being dented. The groove portion GV is defined in a depth not passing through the base layer BL.

The groove portion GV may be defined relatively adjacent to the display region DA, and may be filled by the second encapsulation insulation layer IL2. The groove portion GV may have a shape of a closed line surrounding the hole region HA, or a shape of an intermittent line surrounding at least a portion of the boundary of the groove portion GV in a plan view, and the shape is not limited to any one embodiment of the invention.

The end of the first insulation layer 10 may have a shape protruding at each of the groove portions GV to have an undercut. The second electrode EL2 is severed by the groove portion GV. Since the display panel DP according to an embodiment of the invention may further define the groove portion GV therein, it may be possible to sever the continuous second electrode EL2 which might become a permeation pathway for external moisture or oxygen, thereby preventing damages to elements disposed in the display region DA.

Although not illustrated in the drawing, a partial pattern separated from the second electrode EL2 may be disposed inside the groove portion GV, and may be covered by at least one of the first encapsulation insulation layer IL1 or the third encapsulation insulation layer IL3. Accordingly, it may be possible to prevent the partial pattern from moving to and affecting another element during a manufacturing process of the display panel DP. Therefore, the display panel DP may have improved process reliability. Meanwhile, this is exemplarily illustrated, and in the display panel DP according to an embodiment of the invention, the groove portion GV1 may be provided in plurality, or omitted, and is not limited to any one embodiment of the invention.

The plurality of dams DM1 and DM2 may include a first dam DM1 and a second dam DM2. The first dam DM1 and the second dam DM2 may be disposed in the module region MA. The first dam DM1 may be disposed in the peripheral region SA, and limit a formation region of the second encapsulation insulation layer IL2 to a predetermined compartmental region to prevent additional expansion. It is illustrated that the first dam DM1 may include a stacked structure of a plurality of insulation patterns IP1 and IP2, and the second dam may include a single insulation pattern IP1. However, this is exemplarily illustrated, and the plurality of dams DM1 and DM2 may have a structure of at least three layers, and it is not limited to any one embodiment of the invention.

The planarization pattern OCT includes an organic material. The planarization pattern OCT may be disposed in the module region MA. The planarization pattern OCT covers an uneven surface formed in the module region MA by the plurality of dams DM1 and DM2 or the groove portion GV, and provides a flat surface thereabove. Accordingly, the flat surface may be stably provided even to a region of the module region MA where the second encapsulation insulation layer IL2 is not disposed. The planarization pattern OCT may be optically transparent. In an embodiment, for example, the planarization pattern OCT may have a visible light transmittance of about 90% or more.

Referring to FIG. 8, a window WM may be disposed on the display module DM. The window WM may include a window base layer WBL, a light-blocking layer BML disposed on the window base layer WBL, and a protection layer PF disposed on the light-blocking layer BML. The window WM may further include a window adhesive layer WAL disposed between the window base layer WBL and the protection layer PF to bond the window base layer WBL and the protection layer PF. The light-blocking layer BML may be disposed in a layer the same as a layer in which the window adhesive layer WAL is disposed. However, an embodiment of the invention is not limited thereto, and the window adhesive layer WAL may be omitted in another embodiment.

The window base layer WBL may overlap a display region DA and a non-display region NDA in a plan view. The window base layer WBL may be disposed on a lower side of the window WM to provide a base surface of the window WM. In an embodiment, the window base layer WBL may be a transparent substrate such as a glass substrate, but is not limited thereto, and the window base layer WBL may include plastic in another embodiment.

The window adhesive layer WAL may be disposed on the window base layer WBL. The window base layer WBL and the protection layer PF may be bonded to each other through the window adhesive layer WAL. The window adhesive layer WAL may be optically transparent. The window adhesive layer WAL may be an adhesive layer which is manufactured by applying a liquid adhesive material and then curing, or may be an adhesive sheet which is separately manufactured. In an embodiment, for example, the window adhesive layer WAL may be a pressure sensitive adhesive (“PSA”), an optical clear adhesive (“OCA”), or an optical clear resin (“OCR”).

The light-blocking layer BML may be disposed on the window base layer WBL. The light-blocking layer BML may be disposed on the boundary region of the window WM. In particular, the light-blocking layer BML may overlap the non-display region NDA of the window WM in a plan view. The light-blocking layer BML may overlap the entire non-display region NDA, and may not overlap the display region DA in a plan view. The light-blocking layer BML may be an ink print layer. In addition, the light-blocking layer BML may be a layer defined by including a pigment or dye. The light-blocking layer BML may include a shielding ink layer for shielding light. In an embodiment, for example, the shielding ink layer may include a base material and a shielding ink. The shielding ink may be carbon black particles. However, an embodiment of the invention is not limited thereto, and the shielding ink may include at least one type of pigment, dye, or a mixture thereof in addition to the carbon black particles in another embodiment. By the light-blocking layer BML, it may be possible to prevent inside components of the display device DD overlapping the non-display region NDA from being visible to the outside.

The protection layer PF may be disposed on the window adhesive layer WAL and the light-blocking layer BML. The protection layer PF may be positioned on the uppermost portion of the window WM, and may be a component defining an upper surface of the window WM. That is, an upper surface of the protection layer PF may correspond to the upper surface of the window WM. The protection layer PF may protect the display module DM, etc. disposed under the window WM. In addition, the protection layer PF may further include a functional coating layer. The functional coating layer may include at least one of an anti-fingerprint layer, an anti-reflection layer, or a hard-coating layer.

Referring to FIGS. 6 to 9, in the display device DD according to an embodiment of the invention, the second light-blocking pattern CPT2 of the anti-reflection layer ARL may be disposed in the peripheral region SA of the module region MA, and the light-blocking layer BML of the window WM may not be disposed in the module region MA. Accordingly, by the second light-blocking pattern CPT2 of the anti-reflection layer ARL, it may be possible to prevent a phenomenon in which reflected light generated from a lower part of the electronic module EM is visible to the outside of the display device DD in the hole region HA. In addition, even if the window WM moves on the display module DM in the first direction DR1 or second direction DR2 due to external impact, since the light-blocking layer BML of the window WM is not disposed in the module region MA, it may be possible to prevent a phenomenon in which the module hole MH looks tilted when viewed from the outside of the display device DD. As a result, the aesthetics of the display device DD may be improved.

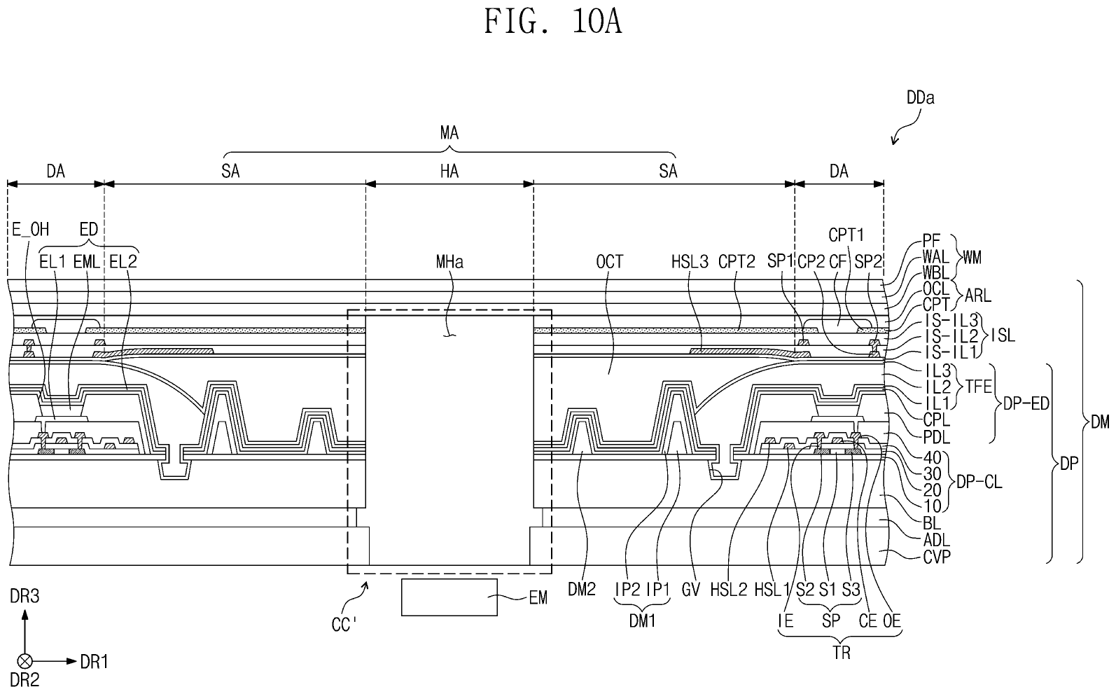

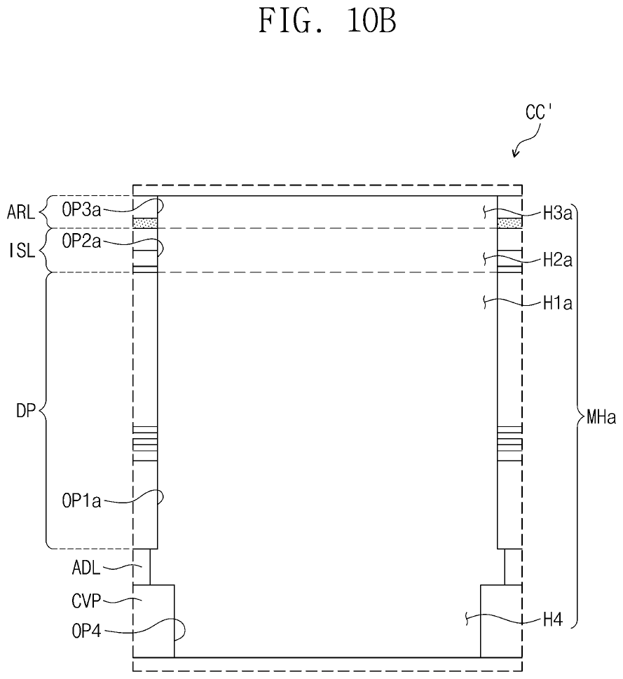

FIG. 10A is a cross-sectional view illustrating a portion of a display

device according to an embodiment of the invention. FIG. 10B is an enlarged view of CC′ region illustrated in FIG. 10A.

Referring to FIGS. 10A and 10B, a display device DDa according to an embodiment of the invention may further include a cover plate CVP under a display panel DP compared to the embodiment illustrated in FIG. 7A. In particular, a display module DM may further include the cover plate CVP under the display panel DP. The cover plate CVP may be disposed on a rear surface of the display panel DP, and may thus improve impact resistance of the display device DDa. The cover plate CVP may be fixed onto the rear surface of the display panel DP through an adhesive layer ADL. The adhesive layer ADL may be a pressure sensitive adhesive (PSA), an optical clear adhesive (OCA), or an optical clear resin (OCR).

The display device DDa may include a module hole MHa defined by passing through a portion of the display device DDa. In an embodiment, for example, the module hole MHa may be defined by passing through the cover plate CVP, the display panel DP, an input-sensing layer ISL, and an anti-reflection layer ARL. At least a portion of an electronic module EM may be disposed in the module hole MHa.

A first opening OP1a may be defined in the display panel DP, a second opening OP2a may be defined in the input-sensing layer ISL, a third opening OP3a may be defined in the anti-reflection layer ARL, and a fourth opening OP4 may be defined in the cover plate CVP. According to an embodiment of the invention, the module hole MHa may include a first hole H1a where the first opening OP1a is defined, a second hole H2a where the second opening OP2a is defined, a third hole H3a where the third opening OP3a is defined, and a fourth hole H4 where the fourth opening OP4 is defined. The first to fourth holes H1a, H2a, H3a, and H4 may extend integrally to form the module hole MHa together.

According to an embodiment of the invention, the size of the fourth hole H4 may be smaller than the size of each of the first to third holes H1a, H2a, and H3a in a plan view. In an embodiment, for example, the sizes of the first to third holes H1a, H2a, and H3a are the same, and the size of the fourth hole H4 may be smaller than the size of each of the first to third holes H1a, H2a, and H3a.

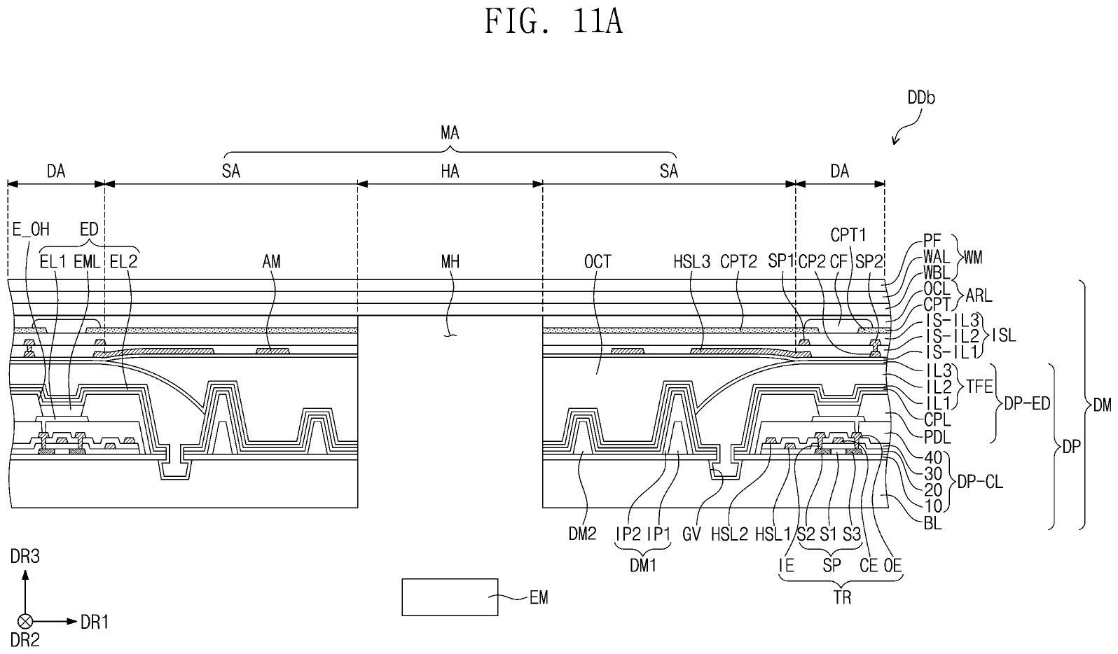

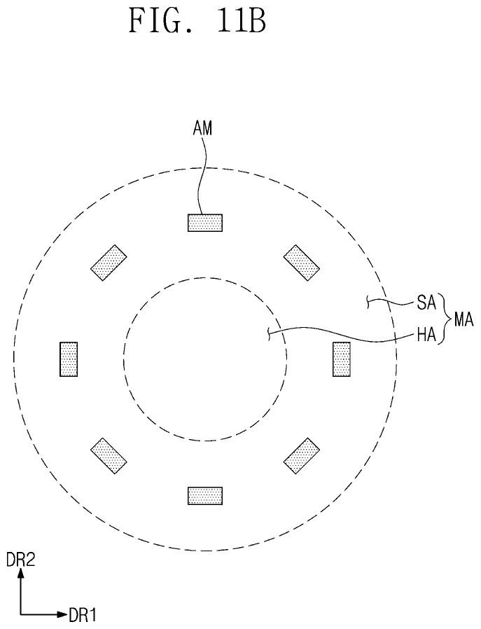

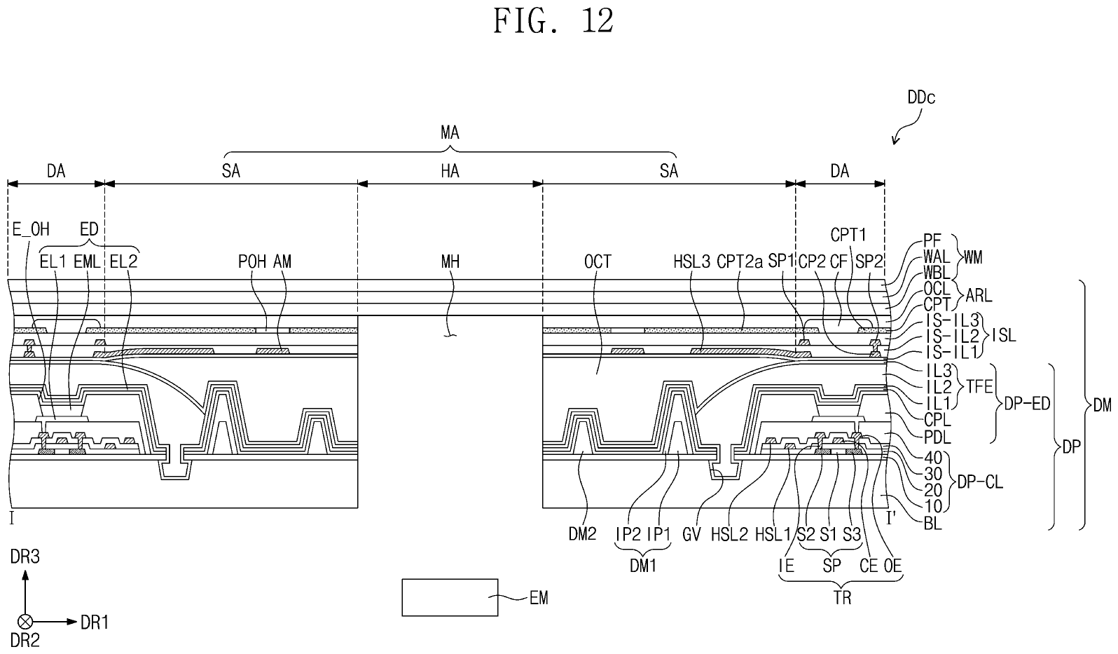

FIG. 11A is a cross-sectional view illustrating a portion of a display device according to another embodiment of the invention. FIG. 11B is a plan view illustrating a portion of the display device illustrated in FIG. 11A. FIG. 12 is a cross-sectional view illustrating a portion of a display device according to still another embodiment of the invention.

Referring to FIG. 11A, a display device DDb according to an embodiment of the invention may further include an alignment mark AM compared to the embodiment illustrated in FIG. 7A. The alignment mark AM may be disposed in a module region MA. In particular, the alignment mark AM may be disposed in a peripheral region SA of the module region MA. The alignment mark AM may be disposed in a layer the same as a layer in which any one among a first sensing pattern SP1, a second sensing pattern SP2, and an auxiliary pattern CP2 is disposed. The first sensing pattern SP1, the second sensing pattern SP2, and the auxiliary pattern CP2 may be collectively referred to as a “sensing pattern”. The alignment mark AM may have a structure extending from a third Hall signal line HSL3. That is, the alignment mark AM may be formed simultaneously with the third Hall signal line HSL3, and then patterned by using a separate mask. FIG. 11A illustrates that the alignment mark AM is disposed between a first sensing insulation layer IS-IL1 and a second sensing insulation layer IS-IL2, but an embodiment of the invention is not limited thereto. For another example, the alignment mark AM may be disposed between the second sensing insulation layer IS-IL2 and a third sensing insulation layer IS-IL3. In another embodiment, the alignment mark AM may be disposed above the third sensing insulation layer IS-IL3 in an embossed or engraved form.

The alignment mark AM may include a metal or inorganic insulating material. The alignment mark AM may be patterned through a dry etching or wet etching, or patterned by using a laser. The alignment mark AM may be formed through various processes, and is not limited to any one embodiment of the invention. The alignment mark AM may be optically opaque.

According to an embodiment of the invention, the alignment mark AM may overlap a second light-blocking pattern CPT2 in a plan view. Accordingly, the alignment mark AM may be invisible to a user when viewed from above the display device DDb, that is, from the opposite direction of a third direction DR3.

Referring to FIG. 11B, the alignment mark AM may have various geometrical patterns identifiable by an alignment device, and it may be easy to identify a pattern with line segments crossing each other. In an embodiment, for example, the alignment mark AM may have a letter shape such as “H”, “T”, “F”, “X”, “¬”, “ [symbol] ”, “⊥”, “ [symbol] ”, etc.

Referring to FIGS. 11A and 11B together, the alignment device (not shown) may align positions of a display module DM and a window WM in order to couple the display module DM and the window WM together. The alignment device includes a camera (not shown), and the camera captures the alignment mark AM from a lower part of the display module DM, that is, toward the opposite direction of the third direction DR3. In this case, the alignment mark AM may not overlap a plurality of dams DM1 and DM2 in a plan view in order to recognize the alignment mark AM. The alignment device may identify the alignment mark AM included in an image received through the camera, and align the positions of the display module DM and the window WM with respect to the identified alignment mark AM. The alignment mark AM may be disposed not only in the module region MA but also in the bezel region BZA of the display device DD illustrated in FIG. 1.

Referring to FIG. 12, a pattern hole POH may be further defined in a second light-blocking pattern CPT2a compared to the embodiment illustrated in FIG. 11A. The pattern hole POH may be defined by patterning the second light-blocking pattern CPT2a. The pattern hole POH may overlap a peripheral region CA in a plan view. An alignment mark AM may overlap the pattern hole POH in a plan view. A camera of an alignment device captures the alignment mark AM from above a display module DM. The alignment device may identify the alignment mark AM included in an image received through the camera, and align positions of the display module DM and a window WM with respect to the identified alignment mark AM.

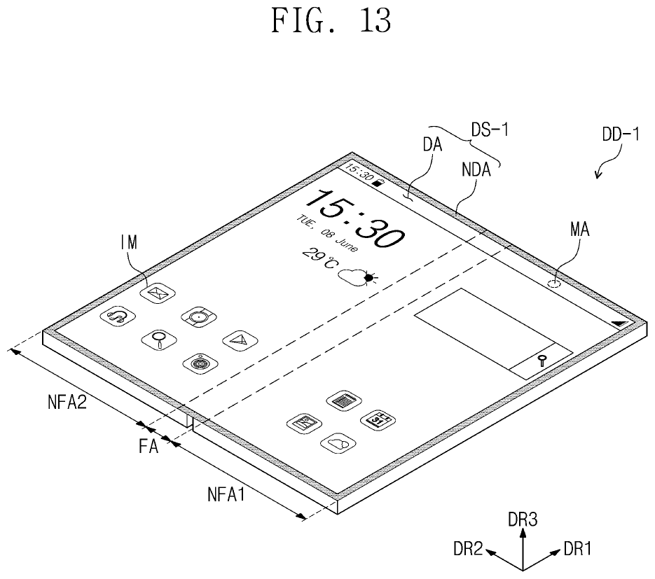

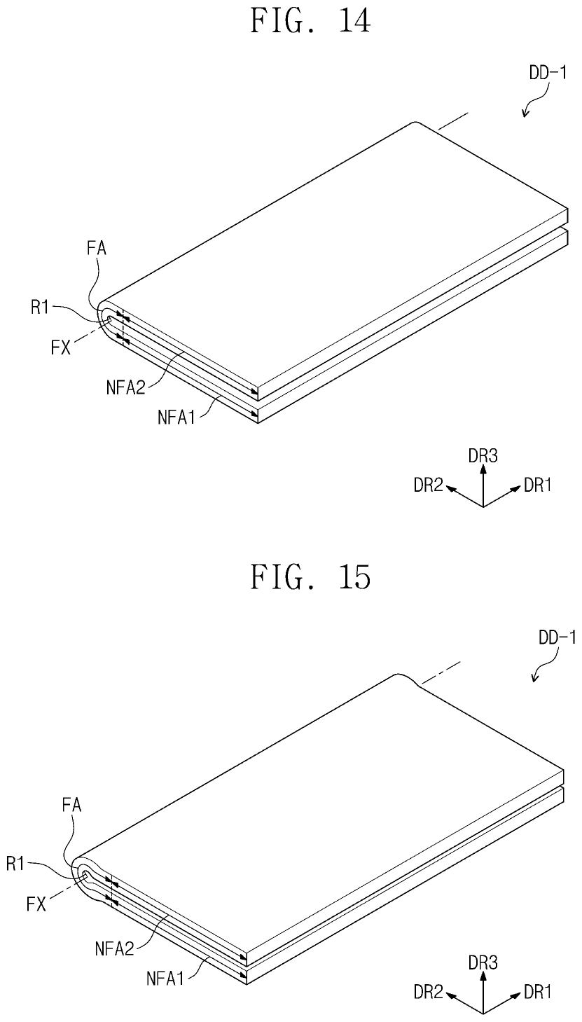

FIGS. 13 to 15 are perspective views of a display device according to an embodiment of the invention. FIG. 13 illustrates a display device DD-1 in an unfolded state, and FIGS. 14 and 15 illustrate the display device DD-1 in a folded state. FIGS. 13 to 15 illustrate a display device according to an embodiment different from the display device DD illustrated in FIG. 1.

Referring to FIGS. 13 to 15, the display device DD-1 according to an embodiment of the invention may include a display surface DS-1 defined by a first direction DR1 and a second direction DR2 crossing the first direction DR1. The display device DD-1 may provide an image IM to a user through the display surface DS-1.

The display surface DS-1 may include a display region DA and a non-display region NDA around the display region DA. The display region DA may display the image IM, and the non-display region NDA may not display the image IM. The non-display region NDA may surround the display region DA. However, an embodiment of the invention is not limited thereto, and the shape of the display region DA and the shape of the non-display region NDA may be changed in another embodiment.

The display surface DS-1 may include a module region MA. The module region MA may be a partial region of the display region DA. The module region MA may have a higher transmittance than the other region of the display region DA. Hereinafter, the other region of the display region DA, except for the module region MA, may be defined as a general display region.

A light signal, for example, visible light or infrared light may move to the module region MA. The display device DD-1 may capture an external image through visible light passing through the module region MA, or determine accessibility of an external object through infrared light. FIG. 13 exemplarily illustrates one module region MA, but an embodiment of the invention is not limited thereto, and the module region MA may be provided in plurality in another embodiment.

The display device DD-1 may include a folding region FA (or bending region) and a plurality of non-folding regions NFA1 and NFA2 (or non-bending regions). The non-folding regions NFA1 and NFA2 may include a first non-folding region NFA1 (or first non-bending region) and a second non-folding region NFA2 (or second non-bending region). In the second direction DR2, the folding region FA may be disposed between the first non-folding region NFA1 and the second non-folding region NFA2.

As illustrated in FIG. 14, the folding region FA may be foldable about a folding axis FX parallel to the first direction DR1. The folding region FA has a predetermined curvature and a predetermined radius of curvature R1. The first non-folding region NFA1 and the second non-folding region NFA2 may face each other, and the display device DD-1 may be inner-folded, so that the display surface DS-1 is not to be exposed to the outside.

Although not illustrated in the drawing, the display device DD-1 may also be outer-folded, so that the display surface DS-1 is to be exposed to the outside. According to an embodiment of the invention, the display device DD-1 may be provided to repeat operations of an unfolding and inner-folding or outer-folding, but an embodiment of the invention is not limited thereto. According to another embodiment of the invention, the display device DD-1 may be provided to select any one among the operations of unfolding, inner-folding, and outer-folding.

As illustrated in FIG. 14, the distance between the first non-folding region NFA1 and the second non-folding region NFA2 may be substantially the same as the radius of curvature R1, but as illustrated in FIG. 15, the distance between the first non-folding region NFA1 and the second non-folding region NFA2 may be smaller than the radius of curvature R1.

According to an embodiment of the invention, in the display device DD-1, as illustrated in FIG. 7A, a second light-blocking pattern CPT2 of an anti-reflection layer ARL may be disposed in the module region MA, and a light-blocking layer BML of a window WM may not be disposed in the module region MA. Accordingly, by the second light-blocking pattern CPT2 of the anti-reflection layer ARL, it may be possible to prevent a phenomenon in which reflected light generated from a lower part of an electronic module EM is visible to the outside of the display device DD-1 in a hole region HA. In addition, even if the window WM moves in the first direction DR1 or second direction DR2 as the display device DD-1 is folded, since the light-blocking layer BML of the window WM is not disposed in the module region MA, it may be possible to prevent a phenomenon in which a module hole MH looks tilted when viewed from the outside of the display device DD-1. As a result, the aesthetics of the display device DD-1 may be improved.

In a display device according to an embodiment of the invention, a second light-blocking pattern of an anti-reflection layer may be disposed in a module region corresponding to a hole defined in a display module. Accordingly, by the second light-blocking pattern of the anti-reflection layer, it may be possible to prevent a phenomenon in which reflected light generated from a lower part of an electronic module is viewed from the outside of the display device in a hole region.

In addition, even if a window moves on the display module due to external impact, etc., since a light-blocking layer of the window is not disposed in the module region, it may be possible to prevent a phenomenon in which a module hole looks tilted, due to the light-blocking layer of the window, when viewed by a user in the outside.

Although the embodiments of the invention have been described, it is understood that the invention should not be limited to these embodiments but various changes and modifications can be made by one ordinary skilled in the art within the spirit and scope of the invention as hereinafter claimed.

Therefore, the technical scope of the invention should not be limited to the contents described in the detailed description of the specification, but should be defined by the claims.

What is claimed is:

1. A display device comprising:
an electronic module; and
a display module in which a module region corresponding to the electronic module and a display region adjacent to the module region are defined, and which includes a display panel having a plurality of pixels and an anti-reflection layer disposed on the display panel,
wherein the anti-reflection layer includes
a first light-blocking pattern which is disposed in the display region and includes a light-blocking material, and in which a plurality of openings are defined corresponding to the plurality of pixels, respectively;
a color filter layer having a plurality of color filters overlapping the openings, respectively, in a plan view; and
a second light-blocking pattern disposed in the module region and having the light-blocking material.

2. The display device of claim 1, wherein the module region comprises a hole region overlapping the electronic module, and a peripheral region surrounding the hole region, and
the second light-blocking pattern overlaps the peripheral region in the plan view.

3. The display device of claim 2, wherein the display module defines a module hole passing through the display panel and the anti-reflection layer and corresponding to the hole region.

4. The display device of claim 3, wherein the module hole comprises a first hole defined by passing through the display panel, and a second hole defined by passing through the second light-blocking pattern, and
a size of the first hole and a size of the second hole in the plan view are the same.

5. The display device of claim 4, wherein the display module further comprises a cover plate disposed under the display panel, and
the module hole further comprises a third hole defined by passing through the cover plate.

6. The display device of claim 5, wherein the size of the first hole is greater than a size of the third hole in the plan view.

7. The display device of claim 2, further comprising a window disposed on the display module.

8. The display device of claim 7, wherein the window comprises:
a window base layer; and
a light-blocking layer disposed on the window base layer.

9. The display device of claim 8, wherein the light-blocking layer does not overlap the module region in the plan view.

10. The display device of claim 9, wherein the display module further comprises a non-display region adjacent to the display region, and
the light-blocking layer overlaps the non-display region.

11. The display device of claim 8, wherein the window further comprises a protection layer disposed on the window base layer, and
the light-blocking layer is disposed between the window base layer and the protection layer.

12. The display device of claim 2, wherein the display module further comprises an input-sensing layer disposed between the display panel and the anti-reflection layer, and including a plurality of insulation layers and a plurality of sensing patterns disposed on at least one of the plurality of insulation layers.

13. The display device of claim 12, wherein the input-sensing layer further comprises an alignment mark disposed under the second light-blocking pattern, and having conductivity.

14. The display device of claim 13, wherein the alignment mark overlaps the peripheral region in the plan view.

15. The display device of claim 14, wherein a pattern hole, overlapping the peripheral region in the plan view, is defined in the second light-blocking pattern, and
the alignment mark overlaps the pattern hole in the plan view.

16. The display device of claim 13, wherein the alignment mark is disposed in a layer the same as a layer in which at least one of the plurality of sensing patterns is disposed.

17. The display device of claim 16, wherein the plurality of insulation layers comprise a first insulation layer and a second insulation layer, and
the alignment mark is disposed between the first insulation layer and the second insulation layer.

18. The display device of claim 1, wherein the first light-blocking pattern and the second light-blocking pattern are integrally connected to each other.

19. The display device of claim 1, wherein a folding region, which is foldable about a virtual folding axis, and a non-folding region, which is not folded, are defined in the display module, and
the module region overlaps the non-folding region.

20. A display device comprising:
an electronic module;
a display module in which a module region corresponding to the electronic module and a display region adjacent to the module region are defined, and which includes a display panel having a plurality of pixels disposed in the display region, an input-sensing layer disposed on the display panel, and a functional layer disposed on the input-sensing layer; and
a window disposed on the display module,
wherein the module region includes
a hole region overlapping the electronic module, and
a peripheral region surrounding the hole region, and
the functional layer includes a module region light-blocking pattern disposed on the input-sensing layer, corresponding to the peripheral region, and having a light-blocking material.

21. The display device of claim 20, wherein the display module defines a module hole passing through the display panel and the functional layer and corresponding to the hole region.

22. The display device of claim 21, wherein the module hole comprises:
a first hole defined by passing through the display panel; and
a second hole defined by passing through the module region light-blocking pattern, and
a size of the first hole and a size of the second hole in a plan view are the same.

23. The display device of claim 22, further comprising a cover plate disposed under the display panel,
wherein the module hole further includes a third hole defined by passing through the cover plate.

24. The display device of claim 23, wherein the size of the first hole is greater than a size of the third hole in the plan view.

25. The display device of claim 20, wherein the window comprises a window base layer, and a light-blocking layer disposed on the window base layer, and
the light-blocking layer does not overlap the module region in a plan view.

26. The display device of claim 20, wherein the functional layer further comprises:
a display region light-blocking pattern which is disposed in the display region and includes the light-blocking material, and in which a plurality of openings are defined corresponding to the plurality of pixels, respectively; and
a color filter layer including a plurality of color filters overlapping the openings, respectively, in a plan view.

27. The display device of claim 20, wherein a folding region, which is foldable about a virtual folding axis, and a non-folding region, which is not folded, are defined in the display module, and
the module region overlaps the non-folding region.
